(19) United States
(12) Patent Application Publication
(10) Pub. No.: US 2023/0083989 A1
(43) Pub. Date: Mar. 16, 2023

(54) SEMICONDUCTOR DEVICE AND METHOD OF MANUFACTURING THE SAME

(71) Applicant: RENESAS ELECTRONICS CORPORATION, Tokyo (JP)

(72) Inventor: Tatsuyoshi MIHARA, Tokyo (JP)

(21) Appl. No.: 17/858,555

(22) Filed: Jul. 6, 2022

(30) Foreign Application Priority Data
Sep. 10, 2021 (JP) 2021-147909

(51) Int. Cl. H01L 27/1159; H01L 27/11587; H01L 27/11592; H01L 21/28; H01L 29/51; H01L 29/66; H01L 29/78

(52) U.S. Cl. CPC H01L 27/1159; H01L 27/11587; H01L 27/11592; H01L 29/40111; H01L 29/516; H01L 29/6684; H01L 29/78391; G11C 11/223

(57) ABSTRACT

Reliability of a semiconductor device including a ferroelectric memory is improved. A gate electrode of a ferroelectric memory is formed on a semiconductor substrate so as to arrange a ferroelectric film therebetween, and a semiconductor layer serving as an epitaxial semiconductor layer is formed on the semiconductor substrate on both sides of the gate electrode. The semiconductor layer is formed on a dent portion of the semiconductor substrate. At least a part of each of a source region and a drain region of the ferroelectric memory is formed in the semiconductor layer.

### CROSS-REFERENCE TO RELATED APPLICATION

The disclosure of Japanese Patent Application No. 2021-147909 filed on Sep. 10, 2021, including the specification, drawings and abstract is incorporated herein by reference in its entirety.

### BACKGROUND

The present invention relates to a semiconductor device and a method of manufacturing the semiconductor device, and is preferably utilized to, for example, a semiconductor device including a ferroelectric memory and a method of manufacturing the same.

As a non-volatile memory operating at a low voltage, a ferroelectric memory including a ferroelectric film is exemplified. In the ferroelectric memory, a writing state and an erasing state are determined in accordance with a polarization direction of the ferroelectric film.

There are disclosed techniques listed below.
[Patent Document 1] Japanese Unexamined Patent Application Publication No. 2021-2611
[Non-Patent Document 1] M. Trentzsch et al., “A 28 nm HKMG super low power embedded NVM technology based on ferroelectric FETs”, 2016 IEEE International Electron Devices Meeting (IEDM)
[Non-Patent Document 2] S. Dunkel et al., “A FeFET based super-low-power ultra-fast embedded NVM technology for 22 nm FDSOI and beyond”, 2017 IEEE International Electron Devices Meeting (IEDM)
Japanese Unexamined Patent Application Publication No. 2021-2611 (Patent Document 1) describes a technique relating to a non-volatile memory. And, Non-Patent Document 1 and Non-Patent Document 2 describe a technique relating to a ferroelectric memory.

### SUMMARY

Improvement of reliability of a semiconductor device including a ferroelectric memory is desired. Other object and novel characteristics will be apparent from the description of the present specification and the accompanying drawings.

According to an embodiment, a semiconductor device including a ferroelectric memory, includes: a semiconductor substrate; agate electrode formed on the semiconductor substrate so as to arrange a ferroelectric film therebetween; and an epitaxial semiconductor layer formed on the semiconductor substrate on both sides of the gate electrode. The epitaxial semiconductor layer is formed on a dent portion of the semiconductor substrate. At least a part of each of a source region and a drain region of the ferroelectric memory is formed in the epitaxial semiconductor layer.

According to an embodiment, a method of manufacturing a semiconductor device including a ferroelectric memory, includes: a step of forming a gate electrode formed on a semiconductor substrate so as to arrange a ferroelectric film therebetween; a step of forming a dent portion by etching the semiconductor substrate; a step of forming an epitaxial semiconductor layer on the dent portion of the semiconductor substrate; and a step of forming a source region and a drain region. At least a part of the source region and the drain region is formed in the epitaxial semiconductor layer.

According to an embodiment, reliability of the semiconductor device can be improved.

### BRIEF DESCRIPTIONS OF THE DRAWINGS

FIG. 1 is a plan view of a principal part of a semiconductor device according to an embodiment.

FIG. 2 is a cross-sectional view of a principal part of a semiconductor device according to an embodiment.

FIG. 3 is a cross-sectional view of a principal part of a semiconductor device according to an embodiment.

FIG. 4 is a cross-sectional view of a principal part of a semiconductor device according to an embodiment.

FIG. 5 is a partially-enlarged cross-sectional view showing an enlarged part of FIG. 4.

FIG. 6 is a cross-sectional view of a principal part in a step of manufacturing a semiconductor device according to an embodiment.

FIG. 7 is a cross-sectional view of a principal part in a step of manufacturing the same semiconductor device as FIG. 6.

FIG. 8 is a cross-sectional view of a principal part in a step of manufacturing the same semiconductor device as FIG. 6.

FIG. 9 is a cross-sectional view of a principal part in a step of manufacturing the semiconductor device, continued from FIG. 6.

FIG. 10 is a cross-sectional view of a principal part in a step of manufacturing the same semiconductor device as FIG. 9.

FIG. 11 is a cross-sectional view of a principal part in a step of manufacturing the same semiconductor device as FIG. 9.

FIG. 12 is a cross-sectional view of a principal part in a step of manufacturing the semiconductor device, continued from FIG. 9.

FIG. 13 is a cross-sectional view of a principal part in a step of manufacturing the same semiconductor device as FIG. 12.

FIG. 14 is a cross-sectional view of a principal part in a step of manufacturing the same semiconductor device as FIG. 12.

FIG. 15 is a cross-sectional view of a principal part in a step of manufacturing the semiconductor device, continued from FIG. 12.

FIG. 16 is a cross-sectional view of a principal part in a step of manufacturing the same semiconductor device as FIG. 15.

FIG. 17 is a cross-sectional view of a principal part in a step of manufacturing the same semiconductor device as FIG. 15.

FIG. 18 is a cross-sectional view of a principal part in a step of manufacturing the semiconductor device, continued from FIG. 15.

FIG. 19 is a cross-sectional view of a principal part in a step of manufacturing the same semiconductor device as FIG. 18.

FIG. 20 is a cross-sectional view of a principal part in a step of manufacturing the same semiconductor device as FIG. 18.

FIG. 21 is a cross-sectional view of a principal part in a step of manufacturing the semiconductor device, continued from FIG. 18.

FIG. 22 is a cross-sectional view of a principal part in a step of manufacturing the same semiconductor device as FIG. 21.

FIG. 23 is a cross-sectional view of a principal part in a step of manufacturing the same semiconductor device as FIG. 21.

FIG. 24 is a cross-sectional view of a principal part in a step of manufacturing the semiconductor device, continued from FIG. 21.

FIG. 25 is a cross-sectional view of a principal part in a step of manufacturing the same semiconductor device as FIG. 24.

FIG. 26 is a cross-sectional view of a principal part in a step of manufacturing the semiconductor device, continued from FIG. 24.

FIG. 27 is a cross-sectional view of a principal part in a step of manufacturing the same semiconductor device as FIG. 26.

FIG. 28 is a cross-sectional view of a principal part in a step of manufacturing the semiconductor device, continued from FIG. 26.

FIG. 29 is a cross-sectional view of a principal part in a step of manufacturing the same semiconductor device as FIG. 28.

FIG. 30 is a cross-sectional view of a principal part in a step of manufacturing the same semiconductor device as FIG. 28.

FIG. 31 is a cross-sectional view of a principal part in a step of manufacturing the semiconductor device, continued from FIG. 28.

FIG. 32 is a cross-sectional view of a principal part in a step of manufacturing the same semiconductor device as FIG. 31.

FIG. 33 is a cross-sectional view of a principal part in a step of manufacturing the same semiconductor device as FIG. 31.

FIG. 34 is a cross-sectional view of a principal part in a step of manufacturing the semiconductor device, continued from FIG. 31.

FIG. 35 is a cross-sectional view of a principal part in a step of manufacturing the same semiconductor device as FIG. 34.

FIG. 36 is a cross-sectional view of a principal part in a step of manufacturing the same semiconductor device as FIG. 34.

FIG. 37 is a cross-sectional view of a principal part in a step of manufacturing the semiconductor device, continued from FIG. 34.

FIG. 38 is a cross-sectional view of a principal part in a step of manufacturing the same semiconductor device as FIG. 37.

FIG. 39 is a cross-sectional view of a principal part in a step of manufacturing the same semiconductor device as FIG. 37.

FIG. 40 is a cross-sectional view of a principal part in a step of manufacturing the semiconductor device, continued from FIG. 37.

FIG. 41 is a cross-sectional view of a principal part in a step of manufacturing the same semiconductor device as FIG. 42.

FIG. 42 is a cross-sectional view of a principal part in a step of manufacturing the same semiconductor device as FIG. 42.

FIG. 43 is a cross-sectional view of a of a semiconductor device according to a study example.

FIG. 44 is a cross-sectional view of a principal part of a semiconductor device according to the study example.

FIG. 45 is a cross-sectional view of a principal part in a step of manufacturing a semiconductor device according to another embodiment.

FIG. 46 is a cross-sectional view of a principal part in a step of manufacturing the same semiconductor device as FIG. 45.

FIG. 47 is a cross-sectional view of a principal part in a step of manufacturing the same semiconductor device as FIG. 45.

FIG. 48 is a cross-sectional view of a principal part in a step of manufacturing the semiconductor device, continued from FIG. 45.

FIG. 49 is a cross-sectional view of a principal part in a step of manufacturing the same semiconductor device as FIG. 48.

FIG. 50 is a cross-sectional view of a principal part in a step of manufacturing the same semiconductor device as FIG. 48.

FIG. 51 is a cross-sectional view of a principal part in a step of manufacturing the semiconductor device, continued from FIG. 48.

FIG. 52 is a cross-sectional view of a principal part in a step of manufacturing the same semiconductor device as FIG. 51.

FIG. 53 is a cross-sectional view of a principal part in a step of manufacturing the same semiconductor device as FIG. 51.

FIG. 54 is a cross-sectional view of a principal part in a step of manufacturing the semiconductor device, continued from FIG. 53.

FIG. 55 is a cross-sectional view of a principal part in a step of manufacturing the semiconductor device, continued from FIG. 54.

FIG. 56 is a cross-sectional view of a principal part in a step of manufacturing the semiconductor device, continued from FIG. 55.

FIG. 57 is a cross-sectional view of a principal part in a step of manufacturing the semiconductor device, continued from FIG. 56.

FIG. 58 is a cross-sectional view of a principal part in a step of manufacturing the semiconductor device, continued from FIG. 57.

FIG. 59 is a cross-sectional view of a principal part in a step of manufacturing the semiconductor device, continued from FIG. 58.

FIG. 60 is a cross-sectional view of a principal part in a step of manufacturing the semiconductor device, continued from FIG. 59.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to the accompanying drawings. Note that components having the same function are denoted by the same reference signs throughout all the drawings for describing the embodiments, and the repetitive description thereof will be omitted. In addition, the description of the same or similar portions is not repeated in principle unless otherwise particularly required in the following embodiments.

Also, in the drawings used for the embodiments, hatching may be omitted even in a cross-sectional view so as to make the drawings easy to see. Further, hatching may be used even in a plan view so as to make the drawings easy to see.

### First Embodiment

<Structure of Semiconductor Device>

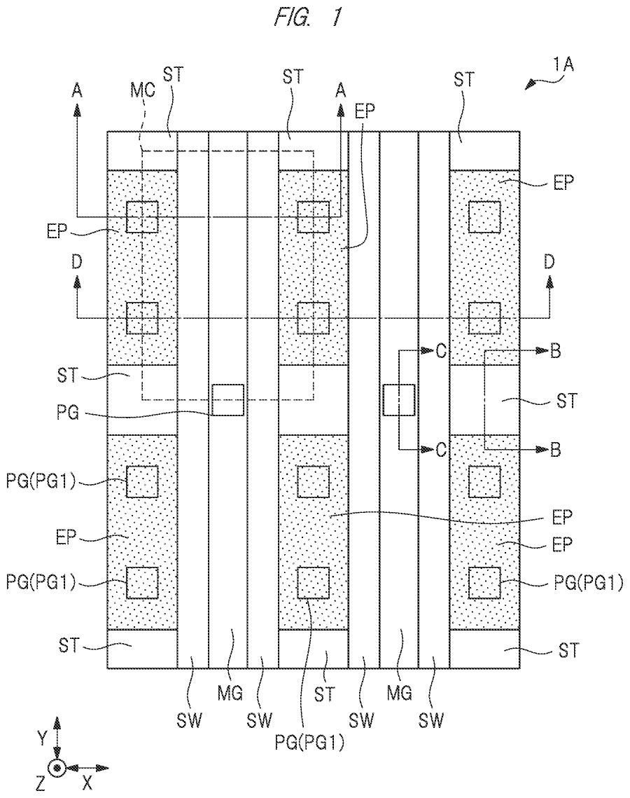

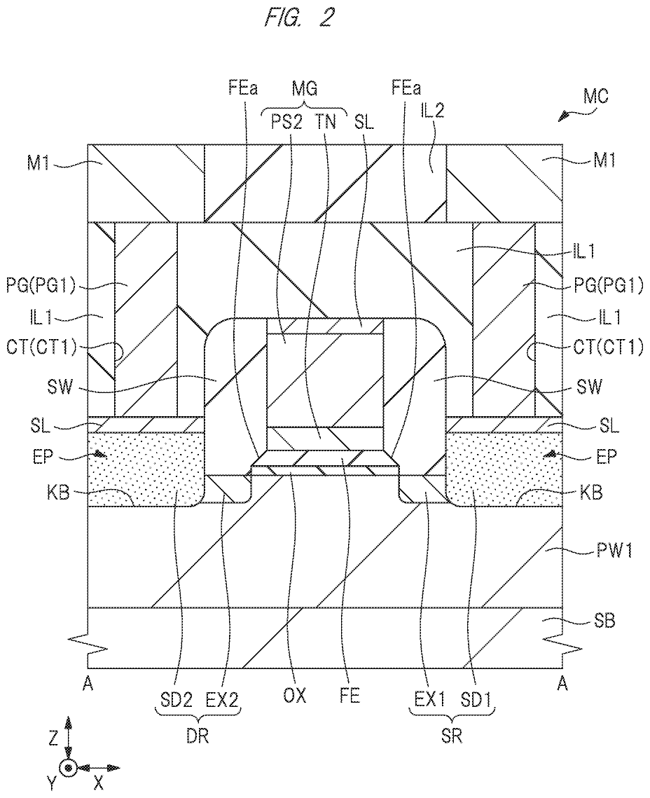

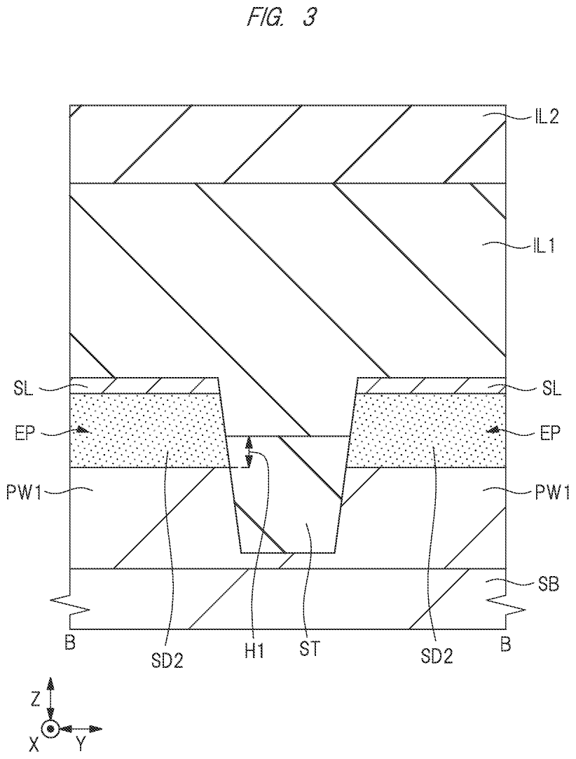

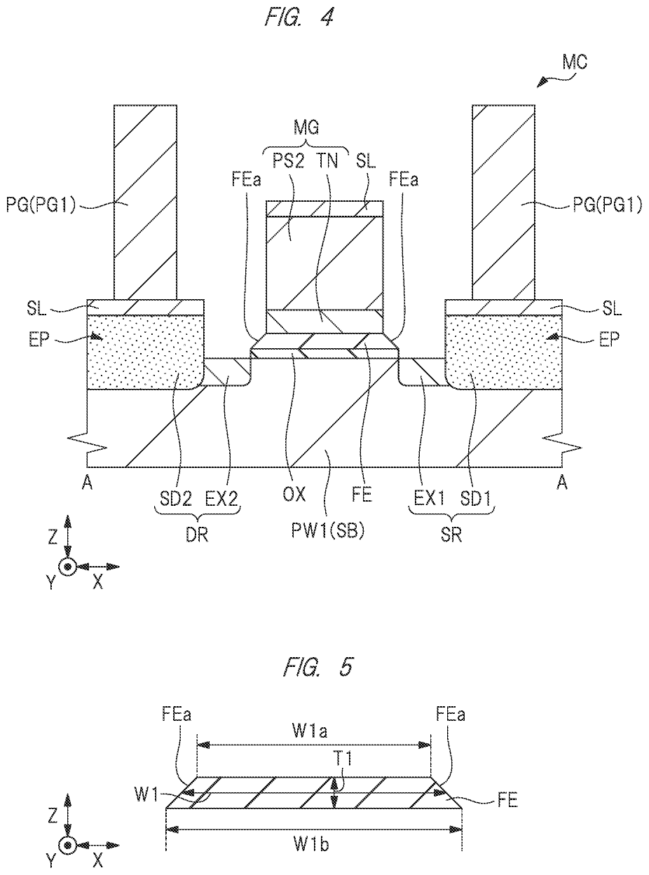

FIG. 1 is a plan view of a principal part of a semiconductor device according to the present embodiment, and each of FIGS. 2 to 4 is a plan view of a principal part of the semiconductor device according to the present embodiment. FIG. 1 illustrates a plan view of a principal part of a memory formation region 1A that is a region where a memory element MC configuring the ferroelectric memory is formed. In the memory formation region 1A, a plurality (a lot) of memory elements MC are arranged in array formation. In FIG. 1, total four memory elements MC expressed by “2×2” are arranged in an X direction and a Y direction in the array formation. However, practically, a lot of memory elements MC are further arranged in the array formation. Although FIG. 1 is a plan view, a dot hatching is added to a semiconductor layer EP for supporting the understanding. A cross-sectional view at a position of a line A-A of FIG. 1 almost corresponds to FIG. 2, and a cross-sectional view at a position of a line B-B of FIG. 1 almost corresponds to FIG. 3. FIG. 4 corresponds to a drawing resulted from exclusion of a sidewall spacer SW, insulating films IL1 and IL2, a plug PG and a wiring M1 from FIG. 2. FIG. 5 is a cross-sectional view showing an enlarged ferroelectric film FE, and corresponds to a drawing resulted from the enlargement of the ferroelectric film FE of FIG. 4. Note that an X direction, a Y direction and a Z direction illustrated in FIGS. 1 to 5 are directions that are orthogonal to one another. The X direction and the Y direction are directions in parallel to a main surface or a back surface of a semiconductor substrate SB, in other words, are horizontal directions. The Z direction is a direction vertical to the main surface or the back surface of the semiconductor substrate SB, in other words, is a thickness direction of the semiconductor substrate SB as well as a height direction of the same. Note that the X direction corresponds to a gate length direction of a gate electrode MG while the Y direction corresponds to a gate width direction of the gate electrode MG.

The semiconductor device of the present embodiment is a semiconductor device including a ferroelectric memory. The memory element (memory cell) MC is a memory element (ferroelectric memory element, a ferroelectric memory cell) configuring the ferroelectric memory. Note that the memory element MC is a planar-type FeFET (Ferroelectric Field Effect Transistor) memory based on a planar-type MISFET. The memory element MC will be explained as an n-channel transistor (MISFET: Metal Insulator Semiconductor Field Effect Transistor) below. However, the explanation is also applicable to a p-channel transistor while a conductive type is opposite.

As illustrated in FIGS. 1 to 4, for example, an element isolation region ST for isolating an element is formed in the semiconductor substrate (semiconductor wafer) SB made of p-type monocrystalline silicon having a specific resistance of about 1 to 10 Ωcm, and an active region is defined by this element isolation region ST. The element isolation region ST is formed by an STI (Shallow Trench Isolation) method. Therefore, the element isolation region ST is made of an insulator (insulating film) embedded in a trench (trench for element isolation) formed in the semiconductor substrate SB. The element isolation region ST is mainly made of silicon oxide. A p-type well PW1 is formed in the active region defined by this element isolation region ST. The p-type well PW1 is a p-type semiconductor region doped with a p-type impurity. The p-type well PW1 is mainly formed in the semiconductor substrate SB in a memory formation region.

A configuration of the memory element MC formed in the memory formation region 1A will be specifically explained below with reference to FIGS. 1 to 5.

The memory element MC includes: the ferroelectric film FE formed on the semiconductor substrate SB (that is on the p-type well PW1) so as to arrange an interface layer OX therebetween; the gate electrode MG formed on the ferroelectric film FE; the sidewall spacer SW formed on both walls of the gate electrode MG; and an n-type semiconductor region SR/DR for source/drain (source or drain) formed on both sides of the gate electrode MG in plan view.

The interface layer OX is made of an insulating film, preferably made of a silicon oxide film, but may be alternatively made of a silicon oxynitride film. The interface layer OX may be eliminated, but is preferably formed. The interface layer OX is arranged between the semiconductor substrate SB and the ferroelectric film FE. However, if the interface layer OX is eliminated, the ferroelectric film FE is formed on the semiconductor substrate SB to be in contact with the semiconductor substrate SB. A thickness of the interface layer OX can be made thinner than that of the ferroelectric film FE to be, for example, about 1 to 2 nm.

The ferroelectric film FE is the film functioning as a gate insulating film arranged between the semiconductor substrate SB (p-type well PW1) and the gate electrode MG. If the interface layer OX is formed, a stacking film of the interface layer OX and the ferroelectric film FE on the interface layer OX may function as the gate insulating film arranged between the semiconductor substrate SB (p-type well PW1) and the gate electrode MG.

The ferroelectric film FE is made of a ferroelectric substance, and has a feature causing charge polarization by application of an electric field and maintaining a polarization state even after the application of the electric field stops. A crystal structure of the ferroelectric film FE is mainly made of an orthorhombic crystal system, and thus, provides the property of the ferroelectric substance. A material of the ferroelectric film FE has, for example, a higher permittivity than that of silicon nitride, is preferably a film containing hafnium (Hf), zirconium (Zr) and oxygen (O) as component elements, and is more specifically a HZO film. Here, the HZO film is made of a mixed crystal of hafnium oxide (HfO₂) and zirconium oxide (ZrO₂), and can be typically expressed as HfₓZr₁₋ₓO₂. Note that “HZO” is an abbreviated expression of hafnium zirconium oxide.

A side surface (end surface) FEa of the ferroelectric film FE has a tape shape. In other words, the side surface FEa of the ferroelectric film FE is not vertical to but tilts to a surface of the semiconductor substrate SB below the ferroelectric film FE. Here, having the taper shape is important for the side surface FEa extending in the Y direction (gate width direction), in other words, the side surface FEa substantially in parallel to the Y direction (gate width direction). Note that a direction vertical to each sheet of FIGS. 2 and 4 is the Y direction.

Specifically, the side surface of the ferroelectric film FE tilts such that a width (size) W1 of the ferroelectric film FE in the X direction is larger as a portion of the side surface of the ferroelectric film FE is closer from an upper surface of the ferroelectric film FE to a lower surface of the ferroelectric film FE (in other words, closer to the semiconductor substrate SB). In other words, the closer to the semiconductor substrate SB the width W1 of the ferroelectric film FE in the X direction is, the larger the width is. Here, the X direction is the gate length direction of the gate electrode MG. Therefore, as illustrated in FIG. 5, a width (size) W1b of the lower surface of the ferroelectric film FE in the X direction is larger than a width (size) W1a of the upper surface of the ferroelectric film FE in the X direction (that is “W1b>W1a”). A thickness T1 of the ferroelectric film FE is, for example, about 5 to 15 nm. In cross-sectional view (more specifically cross-sectional view substantially vertical to the Y direction as illustrated in FIGS. 2, 4 and 5), a difference (W1b-W1a) between the width W1b of the lower surface of the ferroelectric film FE in the X direction and the width W1a of the upper surface of the ferroelectric film FE in the X direction is, for example, about 10 to 30 nm. The width W1a of the upper surface of the ferroelectric film FE in the X direction is almost the same as the gate length (in other words, the width in the X direction) of the gate electrode MG. The gate length of the gate electrode MG can be designed to be, for example, about 20 to 40 nm. Note that the upper surface of the ferroelectric film FE is a surface adjacent to the gate electrode MG (here, the titanium nitride film TN), and the lower surface of the ferroelectric film FE is a surface opposite to the upper surface of the ferroelectric film FE.

The gate electrode MG is formed on the semiconductor substrate SB (p-type well PW1) so as to arrange the interface layer OX and the ferroelectric film FE therebetween. The gate electrode MG extends in the Y direction.

The gate electrode MG is made of a conductive film that may be made of a single film or a stacking film. In the cases of FIGS. 2 and 4, the gate electrode MG is made of a stacking film of the titanium nitride film TN formed on the ferroelectric film FE and a silicon film PS2 formed on the titanium nitride film TN. This silicon film PS2 is preferably a polysilicon (polycrystalline silicon) film. The silicon film PS2 configuring the gate electrode MG can be designed to be a doped polysilicon film doped with an n-type impurity. However, as a different aspect, this can be also designed to be a doped polysilicon film doped with a p-type impurity or a non-doped polysilicon film that is purposely not doped with an impurity. A thickness of the titanium nitride film TN can be designed to be, for example, about 5 to 15 nm, and a thickness of the silicon film PS2 can be designed to be, for example, about 80 to 120 nm.

A region of the semiconductor substrate SB (p-type well PW1), the region being below the gate electrode MG, is a region where the channel region is to be formed, that is a channel formation region. In the channel formation region, a semiconductor region (a p-type semiconductor region or an n-type semiconductor region) for adjusting a threshold voltage is formed if needed.

On a sidewall of the gate electrode MG, the sidewall spacer SW is formed as a sidewall insulating film. The sidewall spacer SW is made of an insulating film that may be made of a single film or a stacking film.

A pair of n-type semiconductor regions SR and DR are formed so as to arrange the gate electrode MG therebetween in the X direction in plan view, and one (here, the n-type semiconductor region SR) of the pair of n-type semiconductor regions SR and DR functions as the source region of the memory element MC while the other (here, the n-type semiconductor region DR) of the pair of n-type semiconductor regions SR and DR functions as the drain region of the memory element MC.

The n-type semiconductor regions SR and DR have an LDD (Lightly doped Drain) structure. Therefore, the n-type semiconductor region SR is made of an n⁻-type semiconductor region (extension region) EX1 having a low impurity concentration and an n⁺-type semiconductor region SD1 having a higher impurity concentration than that of the n⁻-type semiconductor region EX1. And, the n-type semiconductor region DR is made of an n⁻-type semiconductor region (extension region) EX2 having a low impurity concentration and an n⁺-type semiconductor region SD2 having a higher impurity concentration than that of the n⁻-type semiconductor region EX2.

The n⁻-type semiconductor regions EX1 and EX2 are mainly formed inside the semiconductor substrate SB below the sidewall spacer SW. The n⁺-type semiconductor regions SD1 and SD2 are mainly formed in a semiconductor layer EP on the semiconductor substrate SB. The semiconductor layer EP is an epitaxial semiconductor layer formed on the semiconductor substrate SB by epitaxial growth.

Here, a dent portion (concave portion, recess portion) KB is formed in the main surface of the semiconductor substrate SB, and the semiconductor layer EP is formed on this dent portion KB. In FIGS. 1 to 4, the semiconductor layer EP is illustrated with dot hatching so as to easily recognize the semiconductor layer EP. Since the dent portion KB is formed by etching on the semiconductor substrate SB, a height position of a base surface of the dent portion KB is lower than a height position of the upper surface of the semiconductor substrate SB below the gate electrode MG. The semiconductor layer EP and the semiconductor substrate SB are in contact with each other in the dent portion KB, and the interface layer OX and the ferroelectric film FE are not formed on the base surface and the side surface of the dent portion KB.

When the “height position” is described, the Z direction (in parallel to the thickness direction of the semiconductor substrate SB) is the height direction, and a portion closer to the back surface of the semiconductor substrate SB is at the lower height position while a portion far from the back surface of the semiconductor substrate SB is at the higher height position.

Since the semiconductor layer EP is formed on the dent portion KB, the dent portion KB is filled with the semiconductor layer EP. Since the thickness of the semiconductor layer EP is larger than a depth of the dent portion KB, an upper portion of the semiconductor layer EP protrudes out of the main surface of the semiconductor substrate SB. In other words, one part (lower portion) of the semiconductor layer EP fills the inside of the dent portion KB, and the other part (upper portion) of the semiconductor layer EP protrudes out of the main surface of the semiconductor substrate SB. Therefore, the height position of the upper surface of the semiconductor layer EP is higher than the height position of the upper surface of the semiconductor substrate SB below the gate electrode MG. The height position of the upper surface of the semiconductor layer EP is more preferably higher than the height position of the upper surface of the ferroelectric film FE. A difference between the height position of the upper surface of the semiconductor layer EP and the height position of the upper surface of the semiconductor substrate SB below the gate electrode MG is preferably, for example, about 30 to 40 nm.

The dent portion KB is formed on both sides (both sides in the X direction) of a structure made of the gate electrode MG and the sidewall spacer SW on sidewalls of the gate electrode in plan view. Therefore, the semiconductor layer EP formed on the dent portion KB is formed on both sides (both sides in the X direction) of the structure made of the gate electrode MG and the sidewall spacer SW on sidewalls of the gate electrode in plan view. In other words, the pair of dent portions KB and the semiconductor layers EP formed on the dent portion KB are arranged to put the gate electrode MG therebetween in the X direction.

At least a part of each of the source region (here, the n-type semiconductor region SR and the drain region (here, the n-type semiconductor region DR) of the memory element MC is formed in the semiconductor layer EP. This point will be specifically explained below.

The n⁻-type semiconductor regions EX1 and EX2 are formed to be self-aligned in the gate electrode MG, and are formed below the sidewall spacer SW on the sidewall of the gate electrode MG. Therefore, in the semiconductor substrate SB (p-type well PW1) in the memory formation region 1A, the n⁻-type semiconductor regions EX1 and EX2 are formed in regions that separate from each other to arrange a channel formation region therebetween. The n⁻-type semiconductor regions SD1 and SD2 having the high impurity concentration are formed outside the n⁻-type semiconductor regions EX1 and EX2 (far from the channel formation region). In other words, the n⁻-type semiconductor regions EX1 and EX2 are adjacent to the channel formation region, and the n⁻-type semiconductor regions SD1 and SD2 separate from the channel formation region (separate in the channel length direction) by the n⁻-type semiconductor regions EX1 and EX2 while being formed at positions in contact with the n⁻-type semiconductor regions EX1 and EX2. The n⁻-type semiconductor regions EX1 and EX2 are arranged between the channel formation region and the n⁺-type semiconductor regions SD1 and SD2.

The n⁻-type semiconductor regions EX1 and EX2 are formed inside the semiconductor substrate SB. The n⁺-type semiconductor regions SD1 and SD2 are mainly formed in the semiconductor layer EP. Almost the entire semiconductor layer EP is preferably the n⁺-type semiconductor regions SD1 and SD2, and FIGS. 2 and 4 illustrate this state. Surfaces of the n⁻-type semiconductor regions SD1 and SD2 almost coincide with a surface of the entire semiconductor layer EP.

In the cases of FIGS. 2 and 4, base surfaces (PN junction surfaces) of the n⁺-type semiconductor regions SD1 and SD2 almost coincide with the base surface of the dent portion KB (in other words, the lower surface of the semiconductor layer EP). As a different aspect, the base surfaces (PN junction surfaces) of the n⁻-type semiconductor regions SD1 and SD2 may be at a deeper position (a lower height position) than that of the base surface of the dent portion KB (in other words, the lower surface of the semiconductor layer EP). In this case, the n⁺-type semiconductor regions SD1 and SD2 are formed over a region from the semiconductor layer EP to the semiconductor substrate SB. In other words, a part of the n⁺-type semiconductor regions SD1 and SD2 is formed in the semiconductor substrate SB below the semiconductor layer EP.

As another aspect, the n⁺-type semiconductor regions SD1 and SD2 are formed not in the entire semiconductor layer EP but may be in a part (upper part) of the semiconductor layer EP in some cases. In this case, the base surfaces (PN junction surfaces) of the n⁺-type semiconductor region SD1 and SD2 are positioned in the middle of the thickness of the semiconductor layer EP.

A metal silicide layer (metal compound layer) SL is preferably formed on the surfaces (upper surfaces) of the n⁻-type semiconductor region SD1 and SD2, in other words, on the surface of the semiconductor layer EP by a salicide (Self Aligned Silicide) technique. Since at least the upper part of the semiconductor layer EP is the n⁺-type semiconductor regions SD1 and SD2, the surface (upper surfaces) of the n⁺-type semiconductor regions SD1 and SD2 and the surface (upper surface) of the semiconductor layer EP almost coincide with each other.

The metal silicide layer SL can be designed to be a cobalt silicide layer, a nickel silicide layer, a platinum-added nickel silicide layer or others. In the case of FIGS. 2 and 4, the metal silicide layer SL is also formed on the surface (upper surface) of the silicon film PS2 configuring the gate electrode MG. Although the metal silicide layer SL is preferably formed, this formation can be eliminated if needed.

Since the dent portion KB is formed by the etching on the semiconductor substrate SB, the height position of the base surface of the dent portion KB is lower than the height position of the upper surface of the element isolation region ST (more specifically, the upper surface of the element isolation region ST adjacent to the dent portion KB) as seen from FIG. 3. The height position of the surface (the upper surface) of the semiconductor layer EP on the dent portion KB is higher than the height position of the upper surface of the element isolation region ST. In other words, at the position at which the semiconductor layer EP and the element isolation region ST are adjacent to each other in plan view, the dent portion KB is formed so as to be adjacent to the element isolation region ST, and the semiconductor layer EP is formed on the dent portion KB. Therefore, at the position at which the semiconductor layer EP and the element isolation region ST are adjacent to each other in plan view, the surface of the semiconductor substrate SB is made of the base surface of the dent portion KB, and thus, the height position of the surface of the semiconductor substrate SB adjacent to the element isolation region ST is lower than the height position of the upper surface of the element isolation region ST. A height difference H1 (see FIG. 3) between the base surface of the dent portion KB and the upper surface of the element isolation region ST adjacent to the dent portion KB is preferably equal to or larger than 20 nm (H1≥20 nm), and is most preferably, for example, about 20 to 30 nm.

Next, a structure of a layer upper than the memory element MC will be explained.

On the semiconductor substrate SB, an insulating film IL1 serving as an interlayer insulating film is formed so as to cover the gate electrode MG and the sidewall spacer SW. An upper surface of the insulating film IL1 is flattened. A contact hole (a through hole) CT is formed in the insulating film IL1, and a conductive plug PG serving as a conductor for connection is embedded in the contact hole CT. The metal silicide layer SL is exposed from a base of the contact hole CT, and the plug PG is connected to this metal silicide layer SL. The contact hole CT and the plug embedded therein are formed on the semiconductor layer EP (in other words, on the n⁺-type semiconductor region SD1/SD2), on the gate electrode MG and others.

Here, the contact hole CT formed on the semiconductor layer EP (in other words, on the n⁺-type semiconductor regions SD1 and SD2) is referred to as a contact hole CT1 denoted with a reference sign CT1, and the plug PG embedded in the contact hole CT (in other words. the plug PG arranged on the semiconductor layer EP) is referred to as a plug PG1 denoted with a reference sign PG1.

The plug PG arranged on the semiconductor layer EP is in contact with and electrically connected to the metal silicide layer SL on the surface of this semiconductor layer EP. Therefore, the plug PG arranged on the semiconductor layer EP is electrically connected to the semiconductor layer EP through the metal silicide layer SL on the surface of the semiconductor layer EP. Therefore, the plug PG1 arranged on the n⁻-type semiconductor region SD1 is electrically connected to the n⁺-type semiconductor region SD1 through the metal silicide layer SL on the surface of the n⁺-type semiconductor region SD1, and the plug PG1 arranged on the n⁺-type semiconductor region SD2 is electrically connected to the n⁺-type semiconductor region SD2 through the metal silicide layer SL on the surface of the n⁺-type semiconductor region SD2. The plug PG embedded in the contact hole CT arranged on the gate electrode MG is electrically connected to the gate electrode MG.

A wiring M1 is formed on the insulating film IL1 in which the plug PG is embedded. The wiring M1 is, for example, a damascene wiring, and is embedded in a wiring trench formed in an insulating film IL2 formed on the insulating film IL1. The wiring M1 is electrically connected to the n⁻-type semiconductor region SD1, the n⁻-type semiconductor region SD2, the gate electrode MG and others through the plug PG. Although more wirings and insulating films are formed in the upper layer, illustration and explanation for them will be omitted. The wiring M1 and the wiring in the upper layer than the wiring M1 are not limited to the damascene wiring (embedded wiring), and can be made of a patterned conductor film for wiring, and can be made of, for example, a tungsten wiring, an aluminium wiring or others.

Next, the operations of the memory cell MC will be explained.

At the time of the writing operation, a negative voltage (such as −2 to −5 V) is applied to the gate electrode MG of the selected memory cell MC while 0 V is applied to the p-type well PW1, the n-type semiconductor region SR and the n-type semiconductor region DR to make a first polarization state as the polarization direction of the ferroelectric film FE. In the first polarization state, the polarization direction is a direction heading from the semiconductor substrate SB to the gate electrode MG, and the threshold voltage of the MISFET of the memory cell MC is a high threshold voltage.

At the time of the erasing operation, a positive voltage (such as 2 to 5 V) is applied to the gate electrode MG of the selected memory cell MC while 0 V is applied to the p-type well PW1, the n-type semiconductor region SR and the n-type semiconductor region DR to make a second polarization state as the polarization direction of the ferroelectric film FE. In the second polarization state, the polarization direction is a direction heading from the gate electrode MG to the semiconductor substrate SB, and the threshold voltage of the MISFET of the memory cell MC is a low threshold voltage.

At the time of the reading operation for the memory cell MC, the state of the memory cell MC can be determined to be either the writing state (first polarization state) or the erasing state (second polarization state) by the difference in the threshold voltage of the memory element MC between the writing state (first polarization state) and the erasing state (second polarization state). Specifically, at the time of the reading operation, the writing state or the erasing state is detected by applying a middle voltage between the high threshold voltage and the low threshold voltage to the gate electrode MG of the selected memory cell MC, applying a positive voltage to the n-type semiconductor region DR, applying 0 V to the p-type well PW and the n-type semiconductor region SR (source), and measuring an electric current flowing between the drain and the source.

<Step of Manufacturing Semiconductor Device>

A method of manufacturing the semiconductor device of the present embodiment will be explained with reference to the drawings.

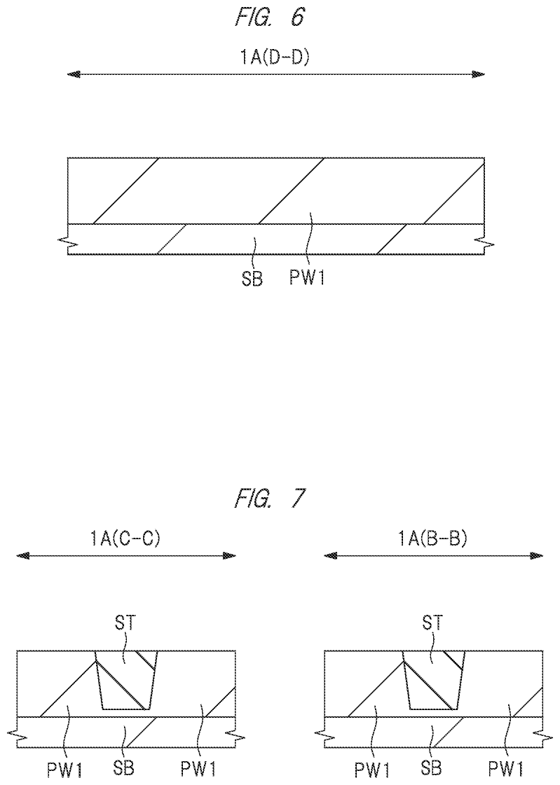

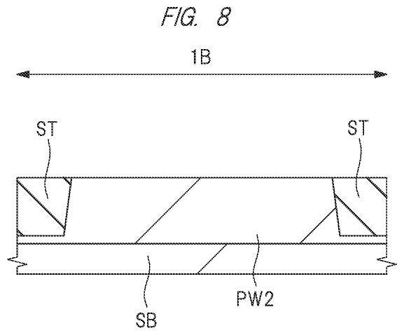

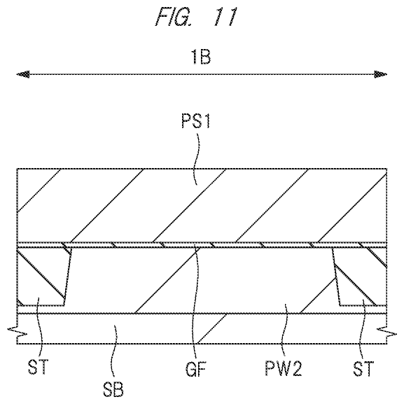

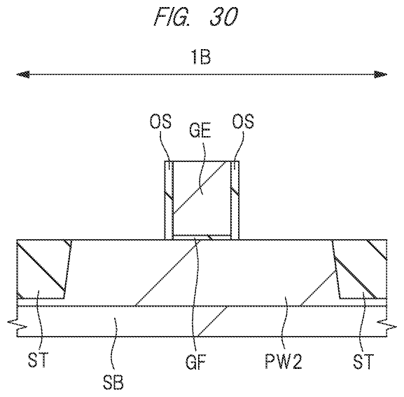

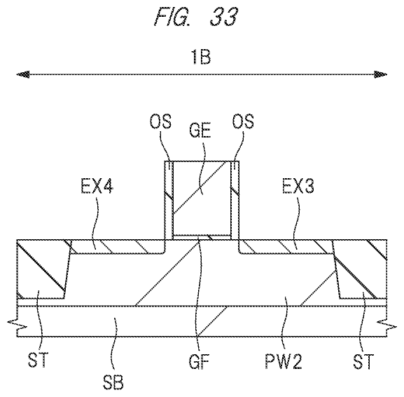

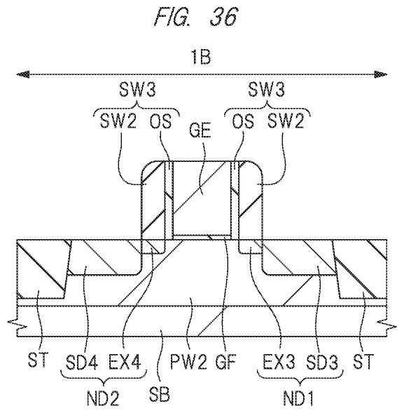

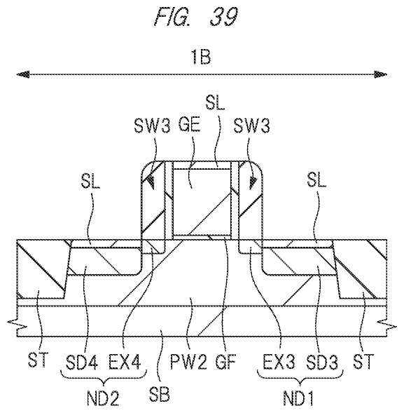

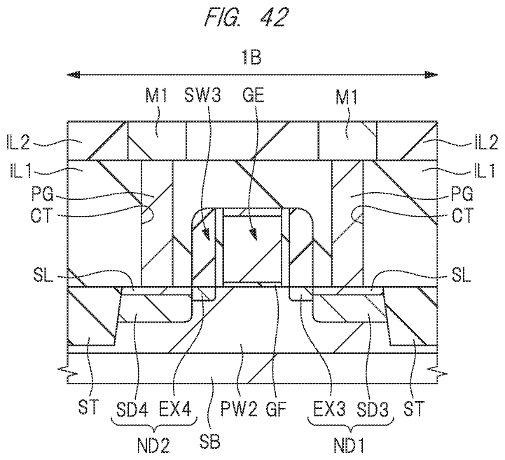

Each of FIGS. 6 to 42 is a cross-sectional view of a principal part in a step of manufacturing the semiconductor device of the present embodiment. Each of FIGS. 6 to 42 illustrates a cross-sectional view of a principal part of a memory formation region 1A or a peripheral circuit region 1B, and illustrate a state in which the memory cell of the ferroelectric memory is formed in the memory formation region 1A while the MISFET configuring the peripheral circuit is formed in the peripheral circuit region 1B. The peripheral circuit region 1B is a region where the peripheral circuit is to be formed in the main surface of the semiconductor substrate SB. The memory formation region 1A and the peripheral circuit region 1B exist in the same semiconductor substrate SB. In other words, the memory formation region 1A and the peripheral circuit region 1B correspond to different planar regions of the main surface of the same semiconductor substrate SB.

In FIGS. 6 to 42, the cross-sectional view denoted with “1A(D-D)” is a cross-sectional view of the memory formation region 1A, and corresponds to a cross-sectional view at a position of a line D-D of FIG. 1. In FIGS. 6 to 42, the cross-sectional view denoted with “1A(B-B)” is a cross-sectional view of the memory formation region 1A, and corresponds to a cross-sectional view at a position of a line B-B of FIG. 1. In FIGS. 6 to 42, the cross-sectional view denoted with “1A(C-C)” is a cross-sectional view of the memory formation region 1A, and corresponds to a cross-sectional view at a position of a line C-C of FIG. 1. In FIGS. 6 to 42, the cross-sectional view denoted with “1B” corresponds to a cross-sectional view of the peripheral circuit region 1B.

Here, the peripheral circuit is a circuit other than the non-volatile memory such as the ferroelectric memory, and includes, for example, a processor such as a CPU, a control circuit, a sense amplifier, a column decoder, a row decoder, an input/output circuit and others. The MISFET formed in the peripheral circuit region 1B is a MISFET for the peripheral circuit. In the present embodiment, a case of formation of an n-channel MISFET in the peripheral circuit region 1B will be explained. However, a p-channel MISFET having an opposite conductive type can be formed in the peripheral circuit region 1B, or both the n-channel MISFET and the p-channel MISFET can be formed in the peripheral circuit region 1B.

In order to manufacture the semiconductor device, the semiconductor substrate (semiconductor wafer) SB made of, for example, p-type monocrystalline silicon having a specific resistance of about 1 to 10Ω is prepared first as illustrated in FIGS. 6 to 8. Then, the element isolation region ST defining the active region is formed in the main surface of the semiconductor substrate SB.

The element isolation region ST is made of an insulator such as silicon oxide, and can be formed by an STI method. Specifically, a trench for the element isolation is formed in the main surface of the semiconductor substrate SB, and then, an insulating film made of, for example, silicon oxide is embedded in this trench for the element isolation, so that the element isolation region ST can be formed.

Next, as illustrated in FIG. 6 to 8, a p-type well PW1 is formed in the semiconductor substrate SB in the memory formation region 1A, and a p-type well PW2 is formed in the semiconductor substrate SB in the peripheral circuit region 1B. The p-type wells PW1 and PW2 can be formed by ion implantation of a p-type impurity such as boron (B) to the semiconductor substrate SB or others. The p-type wells PW1 and PW2 are formed in a region from the main surface of the semiconductor substrate SB down to a predetermined depth.

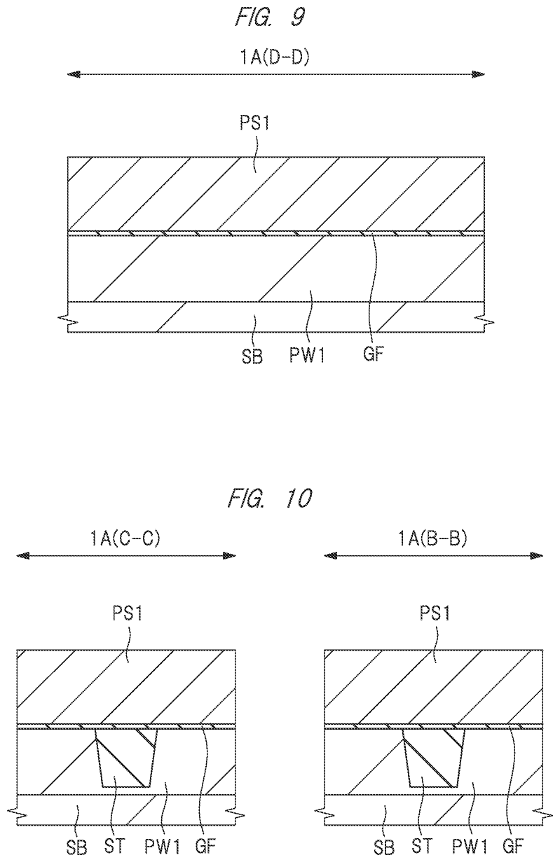

Next, the surface of the semiconductor substrate SB (the p-type wells PW1 and PW2) is rinsed with diluted hydrofluoric acid or others, and then, an insulating film GF is formed on the main surface of the semiconductor substrate SB (surfaces of the p-type wells PW1 and PW2) as illustrated in FIGS. 9 to 11. The insulating film GF can be formed by a thermal oxidation method or others.

Next, as illustrated in FIGS. 9 to 11, as a conductive film for forming a gate electrode GE described later, the silicon film PS1 is formed (deposited) on the main surface (entire main surface) of the semiconductor substrate SB, that is on the insulating film GF. The silicon film PS1 is made of a polycrystalline silicon film, and can be formed by a CVD method or others. However, in the film formation, the silicon film PS1 may be formed as an amorphous silicon film first, and then, the amorphous silicon film may be converted to the polycrystalline film by a later thermal process.

Next, as illustrated in FIGS. 12 to 14, the silicon film PS1 and the insulating film GF in the memory formation region 1A are selectively removed by a photolithography technique and a dry etching technique while the silicon film PS1 and the insulating film GF in the peripheral circuit region 1B are not removed and left.

Next, as illustrated in FIGS. 12 to 14, the silicon oxide film OX1, the ferroelectric film FE, the titanium nitride film TN and the silicon film PS2 are sequentially formed. The titanium nitride film TN and the silicon film PS2 are conductive films for forming the gate electrode MG. The silicon oxide film OX1 can be formed by a thermal oxidation method or others. A silicon oxynitride film can be formed in place of the silicon oxide film OX1. The ferroelectric film FE can be formed by, for example, a CVD (Chemical Vapor Deposition) method, an ALD (Atomic Layer Deposition) method or others. The titanium nitride film TN can be formed by, for example, a sputtering method or others. After the formation of the titanium nitride film TN, a thermal process (annealing) step can be also performed in order to stabilize the ferroelectric property of the ferroelectric film FE. The silicon film PS2 is made of a polycrystalline silicon film, and can be formed by a CVD method or others. However, in the film formation, the silicon film PS2 may be formed as an amorphous silicon film first, and then, the amorphous silicon film may be converted to the polycrystalline film by a later thermal process.

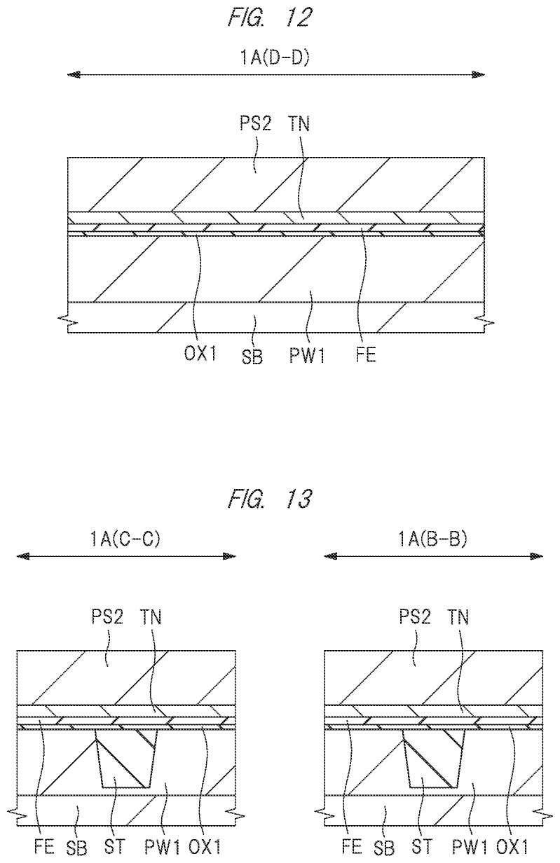

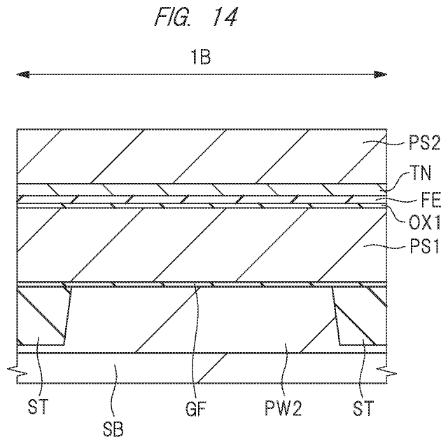

In the memory formation region 1A as illustrated in FIGS. 12 and 13, the silicon oxide film OX1 is formed on a surface of the semiconductor substrate SB (the p-type well PW1), the ferroelectric film FE is formed on this silicon oxide film OX1, the titanium nitride film TN is formed on this ferroelectric film FE, and the silicon film PS2 is formed on this titanium nitride film TN. On the other hand, in the peripheral circuit region 1B as illustrated in FIG. 14, the silicon oxide film OX1 is formed on the silicon film PS1, the ferroelectric film FE is formed on this silicon oxide film OX1, the titanium nitride film TN is formed on this ferroelectric film FE, and the silicon film PS2 is formed on this titanium nitride film TN.

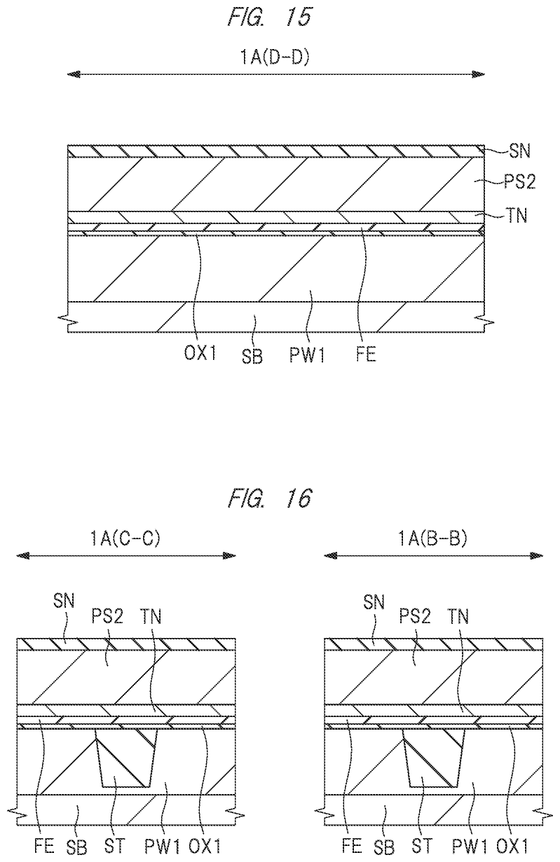

Next, as illustrated in FIGS. 15 to 17, the silicon film PS2, the titanium nitride film TN, the ferroelectric film FE and the silicon oxide film OX1 in the peripheral circuit region 1B are selectively removed by a photolithography technique and a dry etching technique while the silicon film PS2, the titanium nitride film TN, the ferroelectric film FE and the silicon oxide film OX1 in the memory formation region 1A are not removed and left.

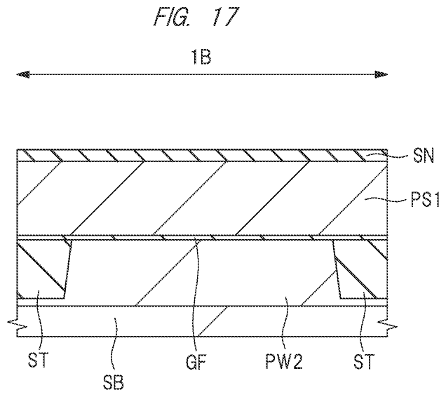

Next, as illustrated in FIGS. 15 to 17, a silicon nitride film SN is formed as an insulating film by a CVD method or others. The silicon nitride film SN is formed on the silicon film PS2 in the memory formation region 1A, and the silicon nitride film SN is formed on the silicon film PS1 in the peripheral circuit region 1B. As a result, in the memory formation region 1A as illustrated in FIGS. 15 and 16, the silicon oxide film OX1, the ferroelectric film FE, the titanium nitride film TN, the silicon film PS2 and the silicon nitride film SN are stacked on the semiconductor substrate SB (the p-type well PW1) in this order from bottom. In the peripheral circuit region 1B as illustrated in FIG. 17, the insulating film GF, the silicon film PS1 and the silicon nitride film SN are stacked on the semiconductor substrate SB (the p-type well PW2) in this order from bottom.

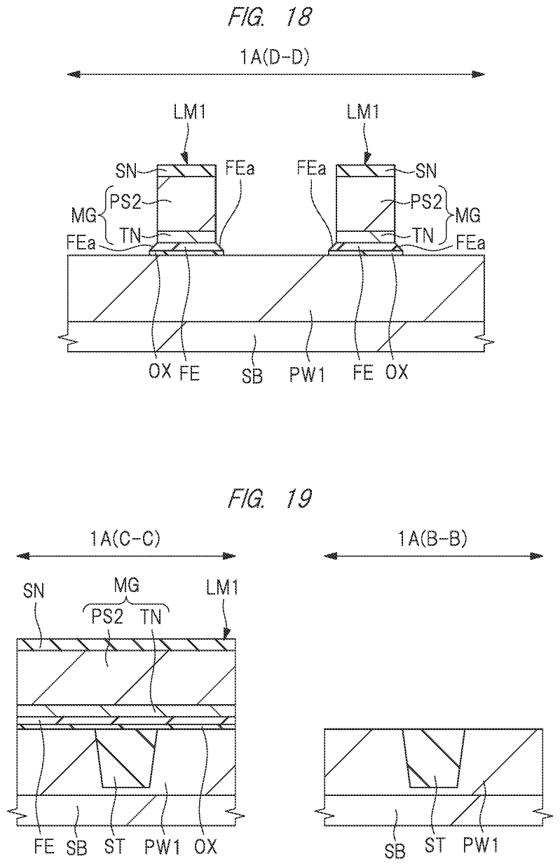

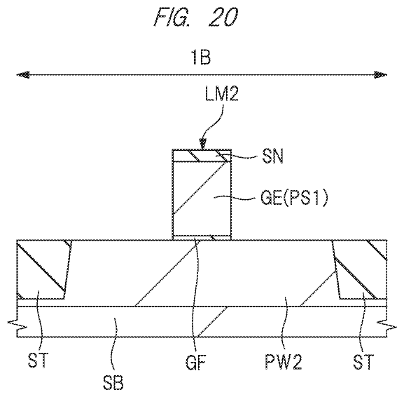

Next, a patterning step using a photolithography method and a dry etching method is performed. In the memory formation region 1A as illustrated in FIGS. 18 and 19, by this patterning step, the stacking film made of the silicon oxide film OX1, the ferroelectric film FE, the titanium nitride film TN, the silicon film PS2 and the silicon nitride film SN is etched and patterned to form a structure body (staking structure body) LM1. In this case, in the memory formation region 1A, the silicon nitride film SN, the silicon film PS2, the titanium nitride film TN, the ferroelectric film FE and the silicon oxide film OX1 are etched in this order. And, in the peripheral circuit region 1B as illustrated in FIG. 20, by this patterning step, the stacking film made of the insulating film GF, the silicon film PS1 and the silicon nitride film SN is etched and patterned to form a structure body (staking structure body) LM2. In this case, in the peripheral circuit region 1B, the silicon nitride film SN, the silicon film PS1 and the insulating film GF are etched in this order.

The structure body LM1 is made of a stacking body made of the interface layer OX, the ferroelectric film FE on the interface layer OX, the gate electrode MG on the ferroelectric film FE, and the silicon nitride film SN on the gate electrode MG, and is formed on the semiconductor substrate SB (the p-type well PW1) in the memory formation region 1A. The gate electrode MG is made of the patterned titanium nitride film TN and silicon film PS2, and the side surface FEa of the ferroelectric film FE configuring the structure body LM1 having the silicon oxide film OX1 left below the ferroelectric film FE as the inter face layer OX is a side surface formed by the etching, and has a taper shape. The structure body LM2 is made of a stacking body made of the insulating film GF, the gate electrode GE on the insulating film GF, and the silicon nitride film SN on the gate electrode GE, and is formed on the semiconductor substrate SB (the p-type well PW1) in the peripheral circuit region 1B. The gate electrode GE is made of the patterned silicon film PS1. Therefore, at this stage, the gate electrode MG is formed on the semiconductor substrate SB in the memory formation region 1A so as to arrange the interface layer OX and the ferroelectric film FE therebetween, and the gate electrode GE is formed on the semiconductor substrate SB in the peripheral circuit region 1B so as to arrange the insulating film GF therebetween.

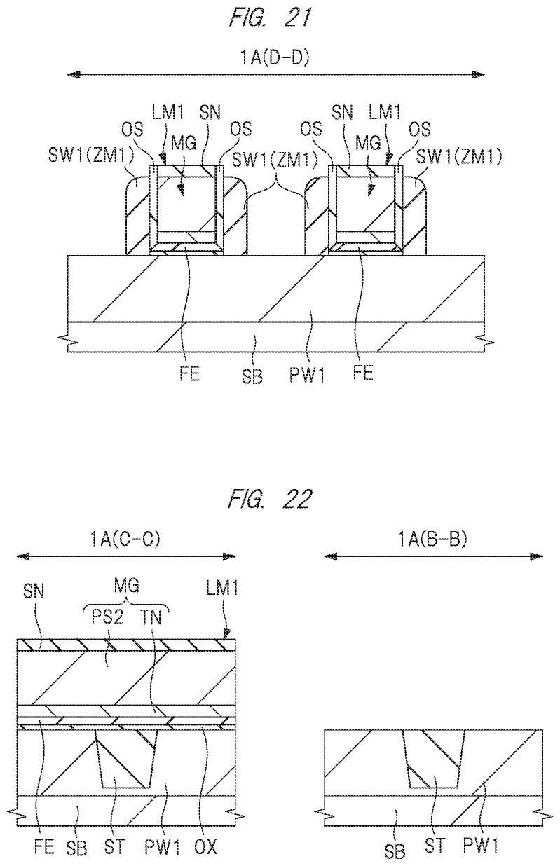

Next, as illustrated in FIGS. 21 to 23, an offset spacer OS made of an insulating film (such as a silicon nitride film) is formed on each sidewall of the structure bodies LM1 and LM2. The offset spacer OS can be formed by forming the insulating film on the semiconductor substrate SB so as to cover the structure bodies LM1 and LM2, and then, etching back this insulating film through an anisotropic etching technique.

Next, on the semiconductor substrate SB, an insulating film ZM1 is formed so as to cover the offset spacer OS on the structure bodies LM1 and LM2 and these sidewalls. The insulating film ZM1 is made of, for example, a single film of a silicon nitride film or a stacking film of a silicon oxide film and a silicon nitride film on the silicon oxide film. Then, the sidewall spacer SW1 is formed on the sidewall of the structure body LM1 so as to arrange the offset spacer OS therebetween as illustrated in FIGS. 21 to 23 by etching back the insulating film ZM1 in the memory formation region 1A through an anisotropic etching technique. The sidewall spacer SW1 is made of the left insulating film ZM1 formed on the sidewall of the structure body LM1 so as to arrange the offset spacer OS therebetween. In this case, as seen from FIG. 23, the insulating film ZM1 in the peripheral circuit region 1B is covered with a photoresist pattern (not illustrated) so as not to be removed and left.

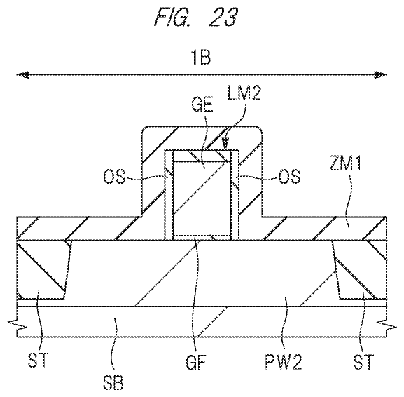

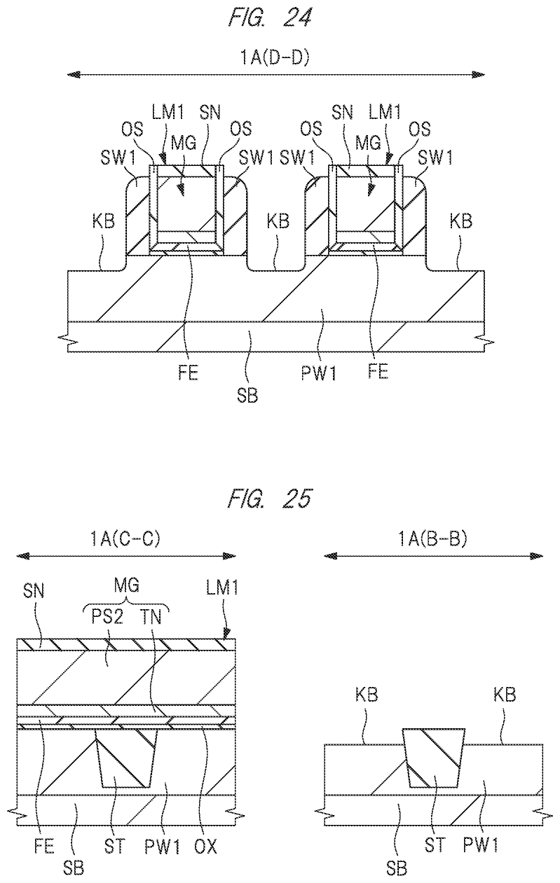

Next, as illustrated in FIGS. 24 and 25, in the memory formation region 1A, the dent portion KB is formed in the semiconductor substrate SB by etching the semiconductor substrate SB. In this case, the structure body LM1, the offset spacer OS and the sidewall spacer SW1 can function as an etching mask. Therefore, a portion of the semiconductor substrate SB covered with the structure body LM1, the offset spacer OS and the sidewall spacer SW1 is not etched, and an exposed portion of the semiconductor substrate SB not covered with the structure body LM1, the offset spacer OS and the sidewall spacer SW1 is etched. Therefore, the dent portion KB is formed in the sidewall spacer SW1 so as to be self-aligned. A depth of the dent portion KB can be designed to be, for example, about 20 to 30 nm.

In the memory formation region 1A, the dent portion KB is adjacent to the element isolation region ST (see FIG. 25). Before the dent portion KB is formed, the height position of the surface of the semiconductor substrate SB and the height position of the upper surface of the element isolation region ST are almost equal to each other (see FIG. 22). However, after the dent portion KB is formed, the height position of the base surface of the dent portion KB is lower than the height position of the upper surface of the element isolation region ST (see FIG. 25). Therefore, after the dent portion KB is formed, a (upper) part of the element isolation region ST in the memory formation region 1A protrudes from the surface of the semiconductor substrate SB (the part being the base surface of the dent portion KB) (see FIG. 25).

An etching step for the formation of the dent portion KB is performed while the semiconductor substrate SB in the peripheral circuit region 1B is covered with the insulating film ZM1 (thus not exposed out) as illustrated in FIG. 23. Therefore, in the etching step for the formation of the dent portion KB, the semiconductor substrate SB in the peripheral circuit region 1B is not etched, and thus, the dent portion KB is formed in the memory formation region 1A but not formed in the peripheral circuit region 1B. Therefore, the peripheral circuit region 1B is in the state of FIG. 23 even at the stage of the formation of the dent portion KB in the memory formation region 1A as illustrated in FIGS. 24 and 25.

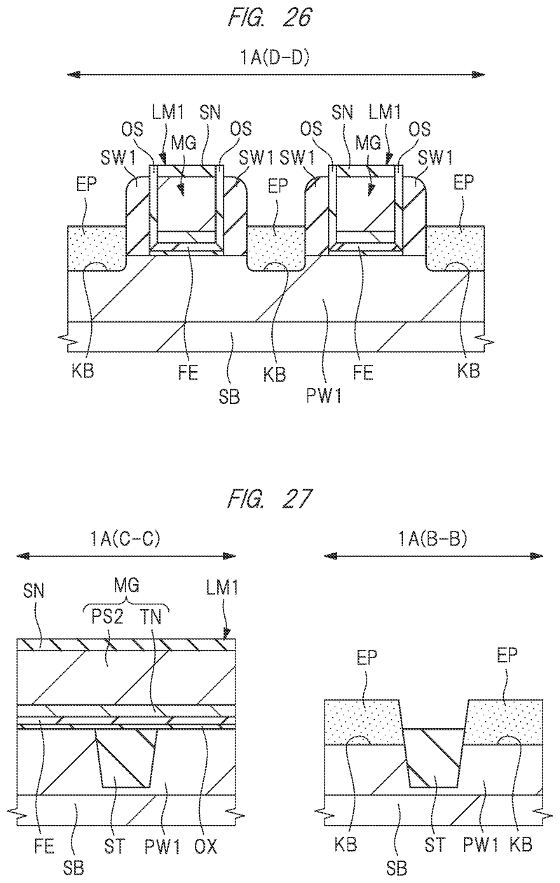

Next, as illustrated in FIGS. 26 and 27, in the memory formation region 1A, the semiconductor layer EP is formed on the dent portion KB of the semiconductor substrate SB by an epitaxial growth method. Since the semiconductor layer EP is formed by the epitaxial growth of the semiconductor layer from the base and side surfaces of the dent portion KB, the dent portion KB is filled with the semiconductor layer EP while the epitaxial growth is continued until the upper surface of the semiconductor layer EP is higher than the height position of the surface of the semiconductor substrate SB below the structure body LM1. The height position of the upper surface of the formed semiconductor layer EP is higher than the height position of the surface of the semiconductor substrate SB below the structure body LM1, and higher than the height position of the upper surface of the element isolation region ST.

A step of the formation of the semiconductor layer EP using the epitaxial growth method is performed while the semiconductor substrate SB in the peripheral circuit region 1B is covered with the insulating film ZM1 (and thus, not exposed out) as illustrated in FIG. 23. Therefore, in the formation of the semiconductor layer EP using the epitaxial growth method, a portion corresponding to the semiconductor layer EP is not formed on the semiconductor substrate SB in the peripheral circuit region 1B. Therefore, the dent portion KB and the semiconductor layer EP are formed in the memory formation region 1A but not formed in the peripheral circuit region 1B. Therefore, the peripheral circuit region 1B is in the state of FIG. 23 even at the stage of the formation of the semiconductor layer EP in the memory formation region 1A as illustrated in FIGS. 26 and 27.

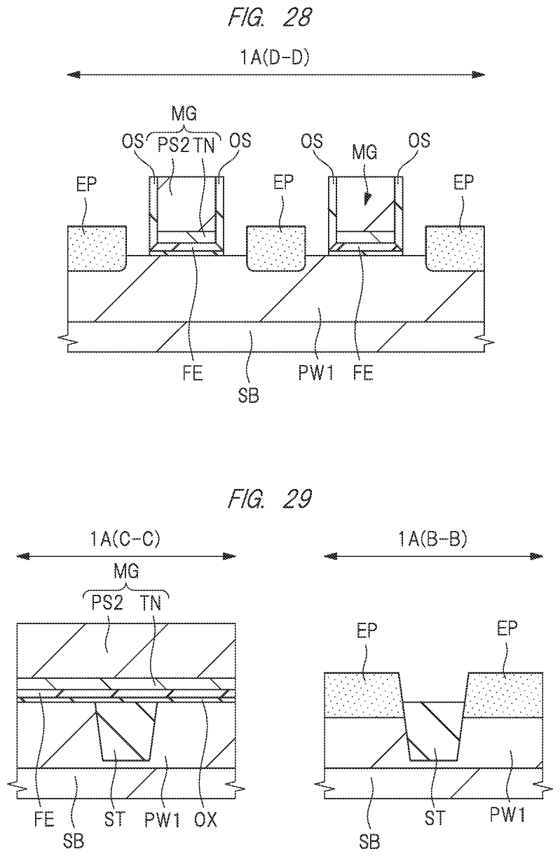

Next, as illustrated in FIGS. 28 to 30, the sidewall spacer SW1, the insulating film ZM1 and the silicon nitride film SN are selectively removed by etching or others. Since the silicon nitride film SN is removed, the structure body LM1 at this stage is made of a stacking body of the interface layer OX, the ferroelectric film FE on the interface layer OX, and the gate electrode MG on the ferroelectric film FE, and the structure body LM2 is a stacking body of the insulating film GF and the gate electrode GE on the insulating film GF. The offset spacer OS can be removed, but is more preferably left.

As another aspect, a sidewall spacer SW2 can be also formed on the sidewall of the structure body LM2 so as to arrange the offset spacer OS therebetween by etching back the insulating film ZM1 in the peripheral circuit region 1B after the formation of the semiconductor layer EP, and then, the sidewall spacer SW2 and the silicon nitride film SN in the memory formation region 1A and the peripheral circuit region 1B can be selectively removed to provide a structure illustrated in FIGS. 28 to 30.

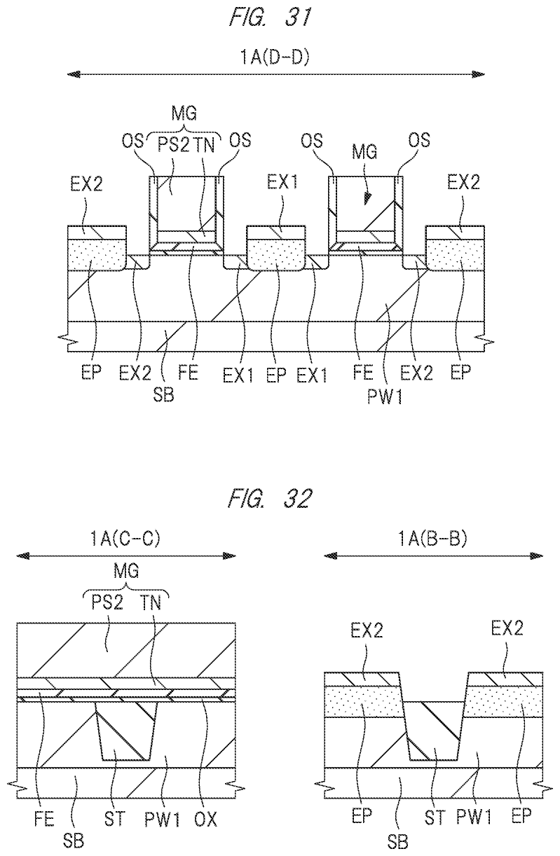

Next, as illustrated in FIGS. 31 to 33, n⁻-type semiconductor regions EX1 and EX2 are formed by the ion implantation of the n-type impurity to the semiconductor substrate SB and the semiconductor layer EP in the memory formation region 1A, and n⁻-type semiconductor regions EX3 and EX4 are formed by the ion implantation of the n-type impurity to the semiconductor substrate SB in the peripheral circuit region 1B. In this ion implantation, the structure bodies LM1 and LM2 can function as masks (ion-implantation blocking masks), and therefore, the n-type impurity is not implanted to a region of the semiconductor substrate SB in the memory formation region 1A, the region being immediately below the structure body LM1, and the n-type impurity is not implanted to a region of the semiconductor substrate SB in the peripheral circuit region 1B, the region being immediately below the structure body LM2.

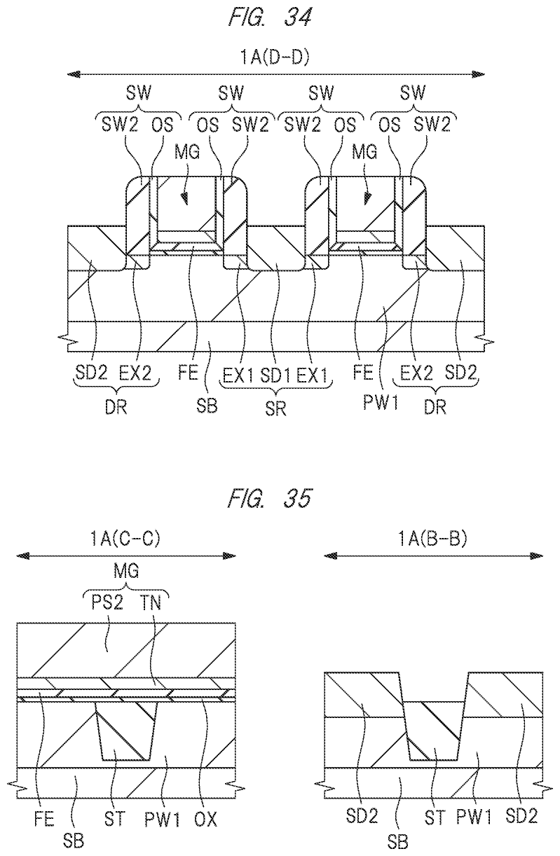

Next, as illustrated in FIGS. 34 to 36, the sidewall spacer SW2 serving as a sidewall insulating film is formed on each sidewall of the structure bodies LM1 and LM2. The sidewall spacer SW2 can be formed by forming an insulating film (such as a silicon nitride film or a silicon oxide film) on the semiconductor substrate SB so as to cover the structure bodies LM1 and LM2, and then, anisotropically etching back this insulating film through an anisotropic etching technique. In the memory formation region 1A, the sidewall spacer SW2 is formed on the sidewall of the structure body LM1 so as to arrange the offset spacer OS therebetween. In the peripheral circuit region 1B, the sidewall spacer SW2 is formed on the sidewall of the structure body LM2 so as to arrange the offset spacer OS therebetween. A combined body of the sidewall spacer SW2 and the offset spacer OS on the sidewall of the structure body LM1 becomes the sidewall spacer SW, and a combined body of the sidewall spacer SW2 and the offset spacer OS on the sidewall of the structure body LM2 becomes a sidewall spacer SW3.

Next, as illustrated in FIGS. 34 to 36, n⁺-type semiconductor regions SD1 and SD2 are formed by implantation of an n-type impurity to the semiconductor substrate SB and the semiconductor layer EP in the memory formation region 1A, and n⁻-type semiconductor regions SD3 and SD4 are formed by implantation of an n-type impurity to the semiconductor substrate SB in the peripheral circuit region 1B. In this ion implantation, the structure bodies LM1 and LM2 and the sidewall spacers SW and SW3 can function as masks (ion-implantation blocking masks). Therefore, the n-type impurity is not implanted to a region of the semiconductor substrate SB in the memory formation region 1A, the region being immediately below the structure body LM1 and the sidewall spacer SW, and the n-type impurity is not implanted to a region of the semiconductor substrate SB in the peripheral circuit region 1B, the region being immediately below the structure body LM2 and the sidewall spacer SW3. In the memory formation region 1A, the n⁺-type semiconductor regions SD1 and SD2 are mainly formed in the semiconductor layer EP, but may be formed in the semiconductor layer EP and the semiconductor substrate SB below this semiconductor layer. The n⁺-type semiconductor regions SD1 and SD2 in the memory formation region 1A have an n-type impurity concentration higher than that of the n⁻-type semiconductor regions EX1 and EX2, and the n⁻-type semiconductor regions SD3 and SD4 the peripheral circuit region 1B have an n-type impurity concentration higher than that of the n⁻-type semiconductor regions EX3 and EX4.

Next, an activation annealing that is a thermal process for activating the impurities that has been implanted up to this step is performed if needed.

In this manner, in the memory formation region 1A, the n-type semiconductor region SR functioning as the source region of the ferroelectric memory is made of the n⁻-type semiconductor region EX1 and the n⁺-type semiconductor region SD1, and the n-type semiconductor region DR functioning as the drain region of the ferroelectric memory is made of the n⁻-type semiconductor region EX2 and the n⁺-type semiconductor region SD2. In the peripheral circuit region 1B, the n-type semiconductor region ND1 functioning as either one of the source region or the drain region of the MISFET is made of the n⁻-type semiconductor region EX3 and the n⁺-type semiconductor region SD3, and the n-type semiconductor region ND2 functioning as the other of the source region or the drain region of the MISFET is made of the n⁻-type semiconductor region EX4 and the n⁻-type semiconductor region SD4.

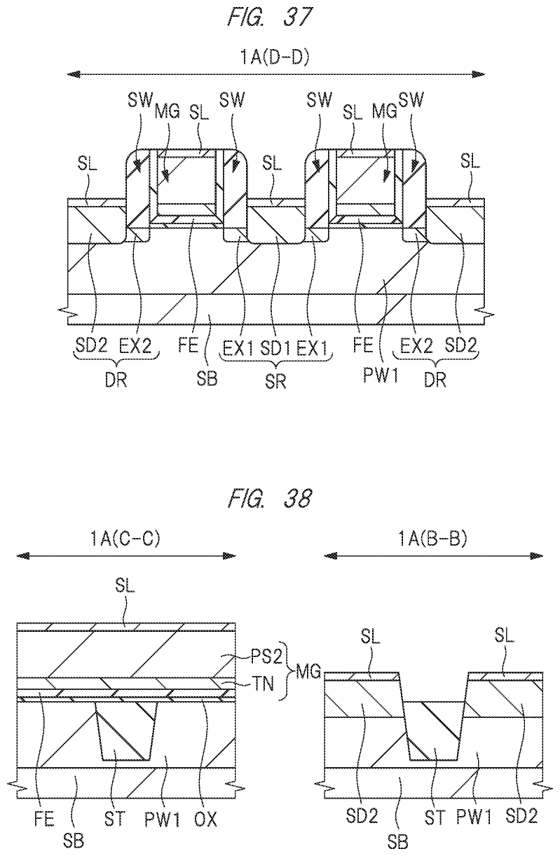

Next, as illustrated in FIGS. 37 to 39, a metal silicide layer SL is formed by a salicide technique. The metal silicide layer SL in the memory formation region 1A is formed in each of the surfaces of the n⁺-type semiconductor regions SD1 and SD2 (that is the surface of the semiconductor layer EP) and the upper surface of the gate electrode MG (that is the upper surface of the silicon film PS2 configuring the gate electrode MG). The metal silicide layer SL in the peripheral circuit region 1B is formed in each of the surfaces of the n⁺-type semiconductor regions SD3 and SD4 and the upper surface of the gate electrode GE (that is the upper surface of the silicon film PS1 configuring the gate electrode GE).

For example, a step of forming the metal silicide layer SL can be performed as follows: A metal film is formed on the main surface of the semiconductor substrate SB so as to cover the gate electrode MG, the sidewall spacer SW and the n⁺-type semiconductor regions SD1 and SD2 (the semiconductor layer EP) in the memory formation region 1A and cover the gate electrode GE, the sidewall spacer SW3 and the n⁺-type semiconductor regions SD3 and SD4 in the peripheral circuit region 1B. This metal film is made of, for example, a cobalt film, a nickel film or a nickel-platinum alloy film. Then, by the thermal process, this metal film in the memory formation region 1A is reacted with the gate electrode MG and the n⁻-type semiconductor regions SD1 and SD2, and this metal film in the peripheral circuit region 1B is reacted with the gate electrode GE and the n⁺-type semiconductor regions SD3 and SD4. As a result, the metal silicide layer SL that is a layer (chemical compound layer) resulted from the reaction between the metal and the semiconductor is formed. Then, the unreacted metal film is removed. Each of FIGS. 37 to 39 illustrates this stage. If the metal film is the nickel film, the metal silicide layer SL is a nickel silicide layer. If the metal film is the nickel-platinum alloy film, the metal silicide layer SL is a nickel-platinum silicide layer.

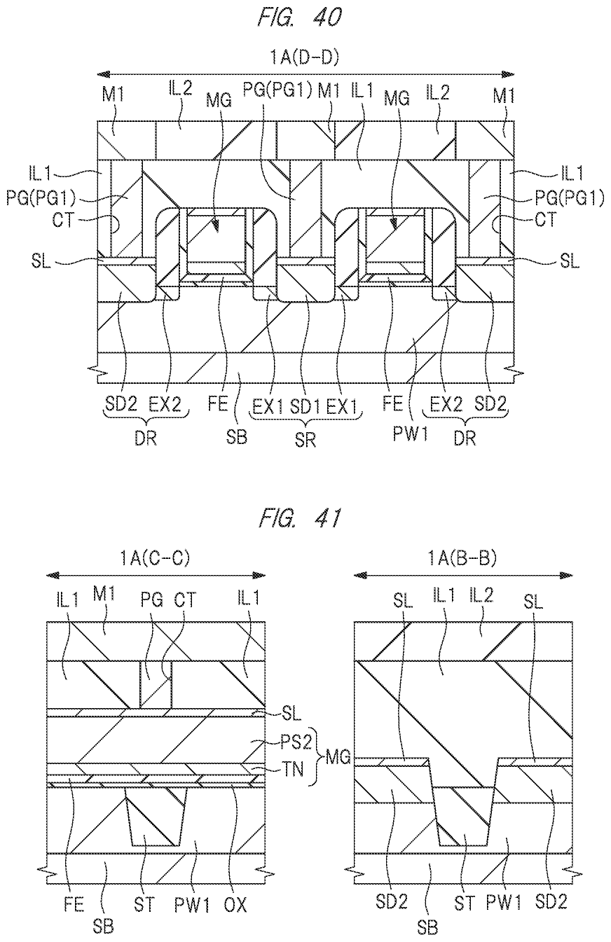

Next, as illustrated in FIGS. 40 to 42, an insulating film IL1 serving as an interlayer insulating film is formed (deposited) on the main surface of the semiconductor substrate SB so as to cover the gate electrodes MG and GE, the sidewall spacers SW and SW3, the semiconductor layer EP and the metal silicide layer SL. An insulating film (such as a silicon oxide film) that is a single layer or a stacking insulating film (such as a stacking film of a silicon nitride film and a silicon oxide film on the film) can be used as the insulating film IL1, and can be formed by, for example, a CVD method or others. After the formation of the insulating film IL1, flatness of an upper surface of the insulating film IL1 can be increased by a CMP method or others polishing the upper surface of the insulating film IL1.

Next, a contact hole (through hole) CT is formed in the insulating film IL1 by a photolithography technique and an etching technique. Then, a conductive plug PG made of tungsten (W) or others is formed as a conductor inside the contact hole CT. In order to form the plug PG, for example, a barrier conductor film is formed on the insulating film IL1 including a base surface and a sidewall of the contact hole CT, and then, a main conductor film made of a tungsten film or others is formed on this barrier conductor film so as to fill the inside of the contact hole CT. Then, the plug PG can be formed by removing the unnecessary main conductor film and barrier conductor film out of the contact hole CT by a CMP method, an etching back method or others.

Next, an insulating film IL2 for wiring formation is formed on the insulating film IL1 to which the plug PG is embedded. Then, a wiring trench is formed in the insulating film IL2 by a photolithography technique and an etching technique, and a wiring M1 is formed inside the wiring trench by a damascene technique. After that, wirings and insulating films in upper layers are formed, but illustration and explanation for them are omitted here.

As described above, the semiconductor device of the present embodiment is manufactured.

<Background of Studies>

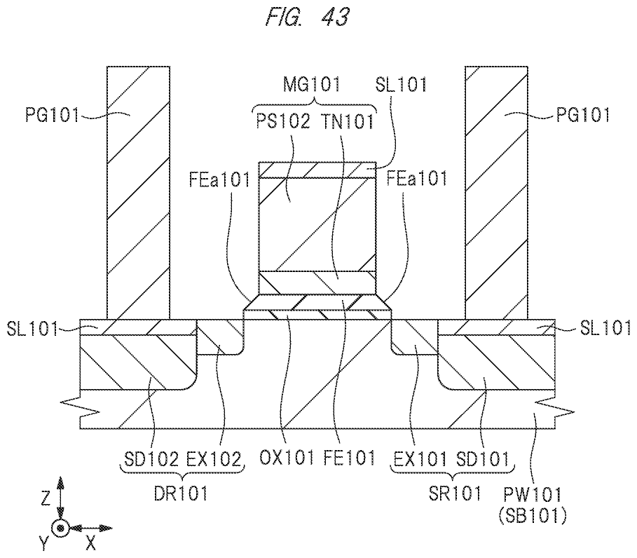

FIG. 43 is a cross-sectional view of a principal part of a semiconductor device of a study example studied by the present inventors, and corresponds to FIG. 4 described above. Also in FIG. 43, illustration of the components corresponding to the above-described insulating films IL1 and IL2, wiring M1 and sidewall spacer SW is omitted as similar to FIG. 4.

The semiconductor device of the study example illustrated in FIG. 43 is also a semiconductor device including a ferroelectric memory. As illustrated in FIG. 43, a gate electrode MG101 for the ferroelectric memory is formed on a semiconductor substrate SB101 (p-type well PW101) so as to arrange an interface layer OX101 and a ferroelectric film FE101 therebetween, and this structure is the same as the structure of the above-described FIG. 4 (the present embodiment). The gate electrode MG101 is made of a stacking film of a titanium nitride film TN101 formed on the ferroelectric film FE101 and a silicon film PS102 formed on the titanium nitride film TN101. A sidewall spacer (not illustrated) is formed on both sidewalls of the gate electrode MG101. An n-type semiconductor region SR101 or DR101 for a source or a drain is formed in the semiconductor substrate SB101 (p-type well PW101) on both sides of the gate electrode MG101. The n-type semiconductor region SR101 is made of an n⁻-type semiconductor region EX101 having a low impurity concentration and an n⁻-type semiconductor region SD101 having a higher impurity concentration than that, and the n-type semiconductor region DR101 is made of an n⁻-type semiconductor region EX102 having a low impurity concentration and an n⁺-type semiconductor region SD102 having a higher impurity concentration than that. A metal silicide layer SL101 is formed on surfaces of the n⁺-type semiconductor region SD101 and SD102 and a surface of the silicon film PS102 configuring the gate electrode MG101. An interlayer insulating film (not illustrated) is formed on the semiconductor substrate SB101 so as to cover the gate electrode MG101, a contact hole is formed in this interlayer insulating film, and a conductive plug PG101 is embedded in this contact hole.

The ferroelectric memory has a structure in which the gate electrode MG101 is formed on the semiconductor substrate SB101 so as to arrange the ferroelectric film FE101 therebtween. Such a structure can be provided by forming, on the semiconductor substrate SB101, the ferroelectric film and the conductive film (conductive film for forming the gate electrode MG101) on this ferroelectric film, and then, etching and patterning the conductive film and the ferroelectric film. However, a ferroelectric film suitable for the ferroelectric memory is a film that is difficult to be etched. When the ferroelectric film is etched, the ferroelectric film is difficult to be side-etched during the etching, and a reaction product caused by etching gas is easy to be deposited during the etching. Therefore, after the etching on the ferroelectric film ends, in other words, after the ferroelectric film FE101 is formed, a side surface FEa101 of the ferroelectric film FE101 has a taper shape. In other words, the side surface FEa101 of the ferroelectric film FE101 tilts such that a width of the ferroelectric film FE101 in the X direction (a gate length direction of the gate electrode MG101) is larger as a portion of the side surface is closer from an upper surface of the ferroelectric film FE101 to a lower surface of the ferroelectric film FE101.

By the studies of the present inventors, it is found that there is a risk of the following problem when the side surface FEa101 of the ferroelectric film FE101 has the taper shape.

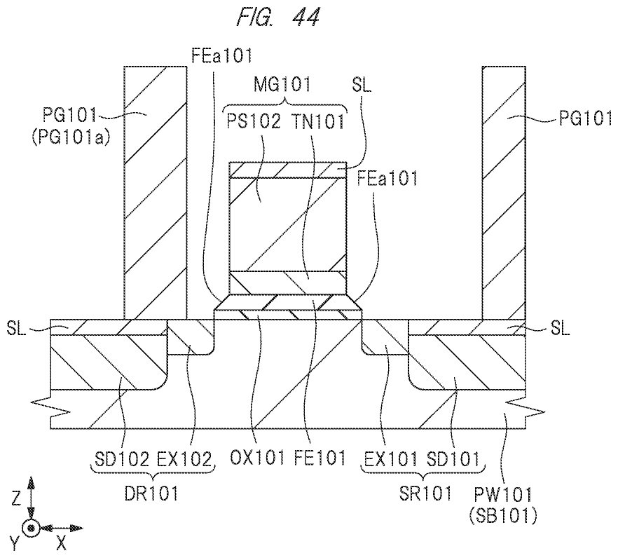

In other words, when the side surface FEa101 of the ferroelectric film FE101 has the taper shape, if the plug PG101 (corresponding to the plug PG101 illustrated in FIGS. 43 and 44) to be connected to the n-type semiconductor region SR101 or DR101 shifts from a design position, the plug PG101 possibly comes close to the ferroelectric film FE101 (see FIG. 44).

Here, FIG. 44 is also a cross-sectional view of a principal part of a semiconductor device according to a study example studied by the present inventors, and corresponds to FIG. 43. However, FIG. 43 corresponds to a case in which the plug PG101 is formed at the design position, and FIG. 44 corresponds to a case in which the formation position of the plug PG101 shifts from the design position. A phenomenon of the shift of the formation position of the plug PG101 from the design position as illustrated in FIG. 44 may occur when, for example, the contact hole (contact hole for burying the plug PG101) is formed in the interlayer insulating film, because of alignment shift of a photomask used for the photolithography technique.

Since the formation position of the plug PG101a illustrated in FIG. 44 shifts from the design position, the plug PG101a is close to the ferroelectric film FE101. Here, the shortest distance between the plug PG101a and the ferroelectric film FE101 when the side surface FEa101 of the ferroelectric film FE101 has the taper shape is smaller than the shortest distance therebetween when the side surface FEa101 of the ferroelectric film FE101 does not have the taper shape. In other words, when the side surface FEa101 of the ferroelectric film FE101 has the taper shape, an X-direction width of a lower surface of the ferroelectric film FE101 is larger than an X-direction width of an upper surface of the ferroelectric film FE101, and therefore, an end of the lower surface of the ferroelectric film FE101 is close to the plug PG101, and thus, the shortest distance between the plug PG101a and the ferroelectric film FE101 is small.

The small shortest distance between the plug PG101a and the ferroelectric film FE101 leads to reduction in reliability of the semiconductor device including the ferroelectric memory, and therefore, is not desirable. For example, a risk of contact between the plug PG101a and the ferroelectric film FE101 arises, and a risk of reduction in a dielectric withstand voltage arises even without the contact.

Therefore, it is necessary to set a margin for sufficiently securing the shortest distance between the plug PG101a and the ferroelectric film FE101 even if the formation position of the plug PG101 shifts from the design position. However, increase in the margin increases a planar size (planar area) of a memory cell of the ferroelectric memory, and thus, increases a planar size of the semiconductor device including the ferroelectric memory. This point is disadvantage to downsize the semiconductor device including the ferroelectric memory.

<Main Feature and Effect>

The semiconductor device of the present embodiment is the semiconductor device including the ferroelectric memory. Therefore, this has the structure in which the gate electrode MG for the ferroelectric memory is formed on the semiconductor substrate SB so as to arrange the ferroelectric film FE therebetween. Such a structure can be provided by forming, on the semiconductor substrate, the ferroelectric film (corresponding to the ferroelectric film FE in the FIG. 15 described above) and the conductive film (corresponding to the titanium nitride film TN and the silicon film PS2 in the FIG. 15 described above) on the ferroelectric film, and then, etching and patterning the conductive film and the ferroelectric film.

One of the main features of the present embodiment is the formation of the semiconductor layer EP that is the epitaxial semiconductor layer on the semiconductor substrate SB on both sides of the gate electrode MG for the ferroelectric memory. The semiconductor layer EP is formed on the dent portion KB of the semiconductor substrate SB, and at least a part of each of the source region (n-type semiconductor region SR) and the drain region (n-type semiconductor region DR) of the ferroelectric memory is formed in the semiconductor layer EP. The source region (n-type semiconductor region SR) and the drain region (n-type semiconductor region DR) can be formed by the ion implantation method.

As explained in the study example, the ferroelectric film suitable for the ferroelectric memory is the film that is difficult to be etched. Therefore, the side surfaces FEa and FEa101 of the ferroelectric films FE and FE101 tend to have the taper shape. As explained above in the study example, when the side surface FEa101 of the ferroelectric film FE101 has the taper shape, if the plug PG101 to be connected to the n-type semiconductor region SR101 or the n-type semiconductor region DR101 shifts from the design position, the plug PG101 possibly comes close to the ferroelectric film FE101.

On the other hand, in the present embodiment, the semiconductor layer EP that is the epitaxial semiconductor layer is formed on the semiconductor substrate SB on both sides of the gate electrode MG for the ferroelectric memory, and at least a part of each of the source region (n-type semiconductor region SR) and the drain region (n-type semiconductor region DR) of the ferroelectric memory is formed in the semiconductor layer EP. On the other hand, in the study example (FIGS. 43 and 44), the one corresponding to the semiconductor layer EP is not formed, and the source region (n-type semiconductor region SR101) and the drain region (n-type semiconductor region DR101) of the ferroelectric memory are formed only inside the semiconductor substrate SB. Therefore, in the present embodiment, even if the plug PG1 to be connected to the n-type semiconductor region SR or the n-type semiconductor region DR shifts from the design position, the plug PG1 can be suppressed or prevented from being close to the ferroelectric film FE in comparison with the study example, and the shortest distance between the plug PG and the ferroelectric film FE can be made larger. This is because the height position of the base surface of the plug PG or PG101 connected to the source region or the drain region of the ferroelectric memory is higher in the present embodiment (FIG. 4) than the study example (FIG. 43), and therefore, the distance between the plug PG or PG101 and the ferroelectric film FE or FE101 is made larger in the present embodiment (FIG. 4) than the study example (FIG. 43) by the height position.

In the present embodiment, the semiconductor layer EP is formed on the semiconductor substrate SB on both sides of the gate electrode MG, and at least a part of the source region or the drain region of the ferroelectric memory is formed in the semiconductor layer EP. Therefore, the height position of the surface of the semiconductor layer EP to be the source region or the drain region can be made high by adjustment of the thickness of the semiconductor layer EP or others. In the present embodiment, the plug PG1 to be connected to the source region or the drain region is necessarily arranged on the semiconductor layer EP, and therefore, the height position of the base surface of the plug PG1 can be made higher in the present embodiment (FIG. 4) than the study example (FIG. 43) not forming the one corresponding to the semiconductor layer EP. In the present embodiment (FIG. 4), the distance between the plug PG and the ferroelectric film FE can be made large by the high height position of the base surface of the plug PG1. As a result, even if the position of the plug PG1 shifts from the design position, the distance between the plug PG and the ferroelectric film FE can be secured, and the plug PG1 can be suppressed or prevented from being close to the ferroelectric film FE. Therefore, the reliability of the semiconductor device including the ferroelectric memory can be improved. For example, the contact between the plug PG1 and the ferroelectric film FE can be more reliably prevented, and the dielectric withstand voltage can be more improved.

Also, in the present embodiment, even if the formation position of the plug PG1 shifts from the design position, the shortest distance between the plug PG1 and the ferroelectric film FE can be secured, and therefore, the design margin can be made small. As a result, the planar size (planar area) of the memory cell of the ferroelectric memory can be also reduced, and the semiconductor device including the ferroelectric memory can be downsized.

Further, in the present embodiment, the semiconductor layer EP is formed on the semiconductor substrate SB on both sides of the gate electrode MG, and therefore, the plug PG1 can be prevented from being close to the ferroelectric film FE even if the position of the plug PG1 shifts from the design position. However, in order to reliably provide this effect, it is more preferable to satisfy the following conditions:

In other words, the height position of the upper surface of the semiconductor layer EP is preferably higher than the height position of the upper surface of the semiconductor substrate SB below the ferroelectric film FE. As a result, the height position of the upper surface of the semiconductor layer EP is higher than the height position of the upper surface of the semiconductor substrate SB in the case (corresponding to the study example) without the formation of the dent portion KB and the semiconductor layer EP, and therefore, the height position of the base surface of the plug PG1 formed on the semiconductor layer EP can be made higher than that of the study example. As a result, even if the position of the plug PG1 shifts from the design position, the distance between the plug PG1 and the ferroelectric film FE can be secured, and the plug PG1 can be suppressed or prevented from being close to the ferroelectric film FE.

The height position of the upper surface of the semiconductor layer EP is more preferably higher than the height position of the upper surface of the ferroelectric film FE. As a result, the height position of the base surface of the plug PG1 formed on the semiconductor layer EP can be made higher than the height position of the upper surface of the ferroelectric film FE. As a result, even if the position of the plug PG1 shifts from the design position, the distance between the plug PG1 and the ferroelectric film FE can be more reliably secured, and the plug PG1 can be more reliably suppressed or prevented from being close to the ferroelectric film FE.

In the present embodiment, even if the side surface FEa of the ferroelectric film FE has the taper shape, the plug PG1 can be made easy to be prevented from being close to the ferroelectric film FE by the formation of the semiconductor layer EP on the semiconductor substrate SB on both sides of the gate electrode MG. Therefore, the present embodiment provides the large effect when being applied to the case in which the side surface FEa of the ferroelectric film FE has the taper shape.

The material film suitable for the ferroelectric film for the ferroelectric memory is the film that is difficult to be etched. When the ferroelectric film is etched, the ferroelectric film is difficult to be side-etched during the etching, and a reaction product caused by etching gas is easy to be deposited during the etching. Therefore, it is not easy to prevent the side surface FEa of the ferroelectric film FE from having the taper shape. In the present embodiment, the tape shape is allowed to be formed on the side surface FEa of the ferroelectric film FE, and therefore, the patterning step for forming the stacking structure of the ferroelectric film FE and the gate electrode MG is easily performed, and the management of the process such as the etching step can be made easy. Therefore, the semiconductor device can be easily manufactured, and a manufacturing yield of the semiconductor device can be improved.

When the side surface FEa of the ferroelectric film FE has the taper shape, the following advantages can be provided. In other words, a vicinity of the side surface FEa of the ferroelectric film FE is damaged by the etching, and therefore, is inferior in the film quality to an inner region of the ferroelectric film FE (an inner region of the vicinity of the side surface FEa). However, a portion of the ferroelectric film FE, the portion being controlled in the polarization state by the voltage application to the gate electrode MG, is a region immediately below the gate electrode MG, while a region out of the gate electrode MG hardly contributes to control for the polarization state. If the side surface FEa of the ferroelectric film FE does not have the taper shape, the side surface FEa of the ferroelectric film FE almost coincides with the side surface of the gate electrode MG, and the vicinity (the damage region) of the side surface FEa of the ferroelectric film FE is positioned immediately below the gate electrode MG. On the other hand, if the side surface FEa of the ferroelectric film FE has the taper shape, the vicinity (the damage region) of the side surface FEa of the ferroelectric film FE protrudes from the gate electrode MG, and does not need to be positioned immediately below the gate electrode MG. Therefore, if the side surface FEa of the ferroelectric film FE has the taper shape, the vicinity (the damage region) of the side surface FEa of the ferroelectric film FE hardly needs to contribute to the control for the polarization state, and the portion having the polarization state controlled by the voltage application to the gate electrode MG is only the region of the ferroelectric film FE, the region being not damaged by the etching damage. In this regard, the property of the ferroelectric film FE is more stable in the case of the taper-shaped side surface FEa of the ferroelectric film FE than the case of the not-taper-shaped side surface FEa of the ferroelectric film FE, and the reliability and the performance of the ferroelectric memory can be more improved.

If the ferroelectric film FE101 is sufficiently thin, the problem explained above in the study example is difficult to occur. However, the ferroelectric films FE and FE101 configuring the ferroelectric memory are relatively thick, and typically have a thickness of 5 to 15 nm. When the side surface FEa101 of the ferroelectric film FE101 having such a thickness has the taper shape, the problem explained above in the study example tends to occur. In the present embodiment, even when the side surface FEa of the ferroelectric film FE has the taper shape, the problem explained above in the study example can be suppressed or prevented from occurring as described above, and therefore, the ferroelectric film FE can be designed to be thick so as to be suitable for the ferroelectric memory.

Even when the ferroelectric film FE101 has the taper shape, if the difference between the X-direction width of the lower surface of the ferroelectric film FE101 and the X-direction width of the upper surface of the ferroelectric film FE101 is sufficiently small, the problem explained above in the study example is difficult to occur. However, it is not easy to achieve this state. In the present embodiment, even when a difference (W1b−W1a) between the X-direction width W1b of the lower surface of the ferroelectric film FE and the X-direction width W1a of the upper surface of the ferroelectric film FE is large, the problem explained above in the study example can be suppressed or prevented from occurring as described above. Therefore, when the difference (W1b−W1a) between the X-direction width W1b of the lower surface of the ferroelectric film FE and the X-direction width W1a of the upper surface of the ferroelectric film FE is large, the present embodiment provides the large effect when being applied to the case in which, for example, the difference (W1b−W1a) is equal to or larger than 10 nm.

The formation of the semiconductor layer EP on the dent portion KB of the semiconductor substrate SB is also one of the main features of the present embodiment. The reason for this will be explained below.

A case of the formation of the semiconductor layer EP on the semiconductor substrate SB on both sides of the gate electrode MG without the formation of the dent portion KB of the semiconductor substrate SB as different from the present embodiment is assumed. In this case, when the semiconductor layer EP is formed by the epitaxial growth method, the semiconductor layer EP possibly grows not only upward but also in a horizontal direction to overstep the element isolation region ST. The element isolation region ST is arranged to electrically isolate the active regions of the semiconductor substrate from each other. However, if the semiconductor layer EP grows in the horizontal direction to overstep the element isolation region ST, there is a risk of short-circuit between the active regions through the semiconductor layer EP overstepping the element isolation region ST. Even if the short-circuit does not occur, there is a risk of reduction in the dielectric withstand voltage. For example, in the cross section illustrated in FIG. 3, if the semiconductor layer EP grows in the horizontal direction to overstep the element isolation region ST, there is a risk of short-circuit between the drain regions (n⁺-type semiconductor regions SD2) of the adjacent ferroelectric memories through the element isolation region ST in the Y direction. Even if the short-circuit does not occur, there is a risk of reduction in the dielectric withstand voltage in the drain regions. In order to prevent this, it is only necessary to increase the width of the element isolation region ST. However, this is disadvantage for the downsizing of the semiconductor device.

On the other hand, in the present embodiment, the dent portion KB is formed in the semiconductor substrate SB, and the semiconductor layer EP is formed on the dent portion KB. In this case, the semiconductor layer EP epitaxially grows from the base surface and the inner wall of the dent portion KB. Therefore, the semiconductor layer EP can be suppressed or prevented from growing in the horizontal direction to overstep the element isolation region ST. As a result, the short-circuit between the active regions through the semiconductor layer EP overstepping the element isolation region ST can be prevented, and the reduction in the dielectric withstand voltage due to the semiconductor layer EP overstepping the element isolation region ST can be prevented. For example, in the cross section illustrated in FIG. 3, the semiconductor layer EP can be suppressed or prevented from growing in the horizontal direction to overstep the element isolation region ST, and therefore, the short-circuit between the drain regions (n⁻-type semiconductor regions SD2) of the adjacent ferroelectric memories through the element isolation region ST in the Y direction can be more reliably prevented, and the reduction in the dielectric withstand voltage in the drain regions can be more reliably prevented. Since the semiconductor layer EP can be suppressed or prevented from growing in the horizontal direction to overstep the element isolation region ST, the short-circuit between the active regions and the reduction in the dielectric withstand voltage can be prevented without the increase in the width of the element isolation region ST, and therefore, the semiconductor device can be downsized.

Further, in the present embodiment, the semiconductor layer EP is formed on the dent portion KB of the semiconductor substrate SB, and therefore, the semiconductor layer EP can be suppressed or prevented from growing in the horizontal direction to overstep the element isolation region ST. However, in order to reliably provide this effect, it is more preferable to satisfy the following conditions:

In other words, the height position of the base surface of the dent portion KB is lower than the height position of the upper surface of the element isolation region ST. As a result, the semiconductor layer EP having grown from the base surface and the inner wall of the dent portion KB can be suppressed from growing in the horizontal direction to overstep the element isolation region ST. And, the height position of the base surface of the dent portion KB is more preferably lower by 20 nm or more than the height position of the upper surface of the element isolation region ST. As a result, the effect for suppressing the semiconductor layer EP having grown from the base surface and the inner wall of the dent portion KB but growing in the horizontal direction to overstep the element isolation region ST can be reliably provided.

When the semiconductor layer EP is formed at a position adjacent to the element isolation region ST, if the semiconductor layer EP is formed without the formation of the dent portion KB, a phenomenon of the overstepping of the semiconductor layer EP on the element isolation region ST tends to occur. Even when the semiconductor layer EP is formed at the position adjacent to the element isolation region ST, the present embodiment can prevent the occurrence of the phenomenon of the overstepping of the semiconductor layer EP over the element isolation region ST adjacent to the dent portion KB since the semiconductor layer EP is formed on the dent portion KB after the dent portion KB is formed.

In the present embodiment, since the semiconductor layer EP is formed on the dent portion KB of the semiconductor substrate SB, the following advantages can be also provided.

In other words, in the present embodiment, since the semiconductor layer EP is formed on the dent portion KB of the semiconductor substrate SB, the depth of each base surface (PN junction surface) of the n⁺-type semiconductor regions SD1 and SD2 in the semiconductor substrate SB can be shallower than that in the case of the formation of the semiconductor layer EP without the formation of the dent portion KB. In other words, the n⁻-type semiconductor regions SD1 and SD2 formed in the semiconductor substrate SB can be thinned. As a result, the influence of the short channel effect can be reduced. Therefore, the performance of the ferroelectric memory can be improved.

### Second Embodiment

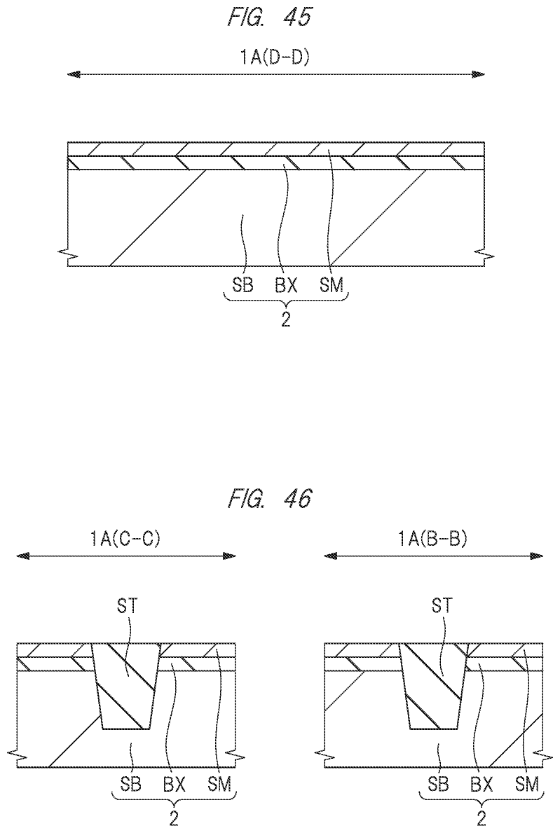

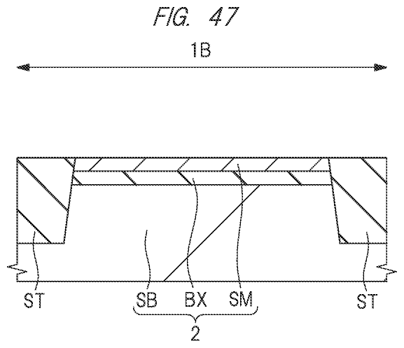

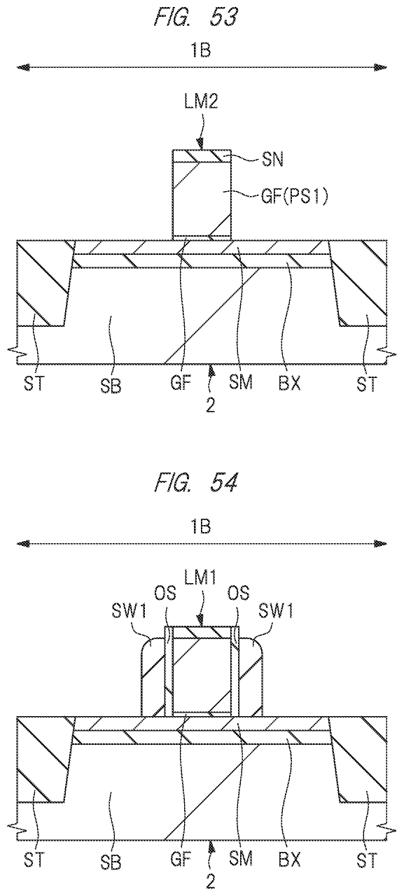

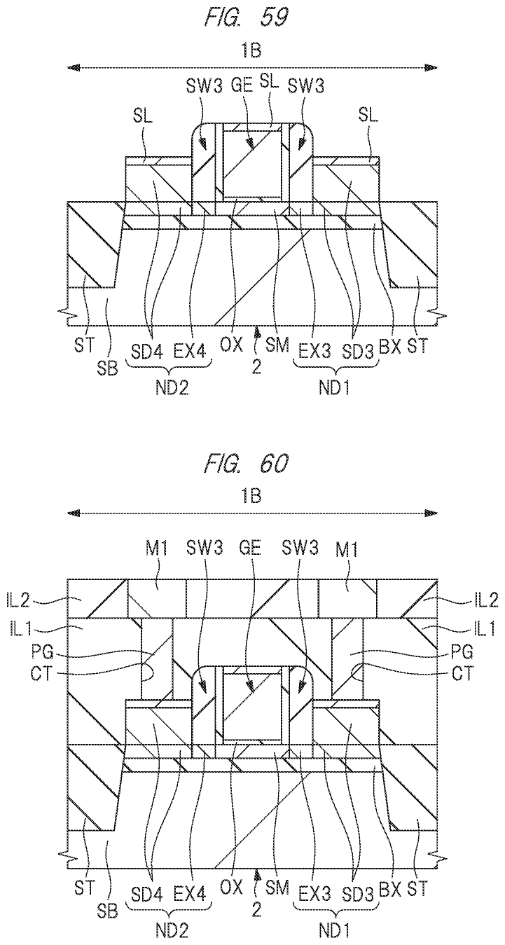

Each of FIGS. 45 to 60 is a cross-sectional view of a principal part in a step of manufacturing a semiconductor device of the present second embodiment. In the above-described first embodiment, note that the ferroelectric memory and the MISFET for the peripheral circuit are formed in the semiconductor substrate SB. In the present second embodiment, a case of formation of the ferroelectric memory and the MISFET for the peripheral circuit in an SOI (Silicon On Insulator) substrate 2 will be explained. Note that the present second embodiment is the same as the first embodiment in the structure of the ferroelectric memory formed in the memory formation region 1A, and therefore, repetitive explanation for this structure is omitted.

First, as illustrated in FIGS. 45 to 47, the SIO substrate 2 is prepared. As seen from FIGS. 45 to 47, the SOI substrate 2 includes a semiconductor substrate SB serving as a support substrate, an insulating layer BX formed on a main surface of the semiconductor substrate SB, and a semiconductor layer SM formed on an upper surface of the insulating layer BX.

The insulating layer BX is preferably a silicon oxide film, and a thickness of the insulating layer BX can be designed to be, for example, about 10 nm to 20 nm. The insulating layer BX can be regarded as a buried oxide film that is a BOX (Buried Oxide) layer. The semiconductor layer SM is made of a monocrystalline silicon or others. The semiconductor layer SM can be made of, for example, a monocrystalline silicon having a specific resistance of about 1 to 10 Ωcm. The semiconductor layer SM can be also regarded as an SOI layer. The semiconductor layer SM is thinner than the semiconductor substrate SB serving the support substrate, and a thickness of the semiconductor layer SM can be designed to be, for example, 15 to 25 nm. The SOI substrate 2 is made of the semiconductor substrate SB, the insulating layer BX and the semiconductor layer SM.

Next, as illustrated in FIGS. 45 to 47, the element isolation region ST is formed. In order to form the element isolation region ST, for example, a trench which penetrates the semiconductor layer SM and the insulating layer BX and a base surface of which reaches the semiconductor substrate SB is formed in the main surface of the SOI substrate 2 by a photolithography technique and an etching technique. Then, by burying an insulating film in this trench, the element isolation region ST can be formed. The element isolation region ST penetrates the semiconductor layer SM and the insulating layer BX, and a base surface of this reaches the middle of the thickness of the semiconductor substrate SB.

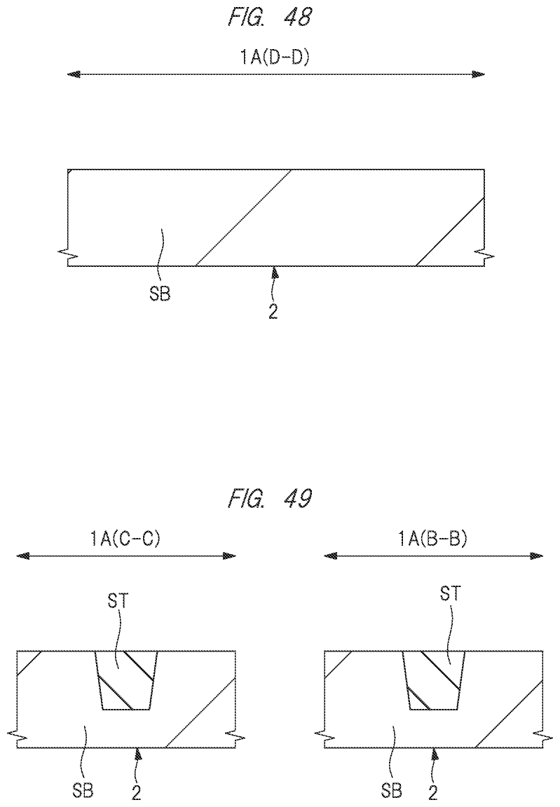

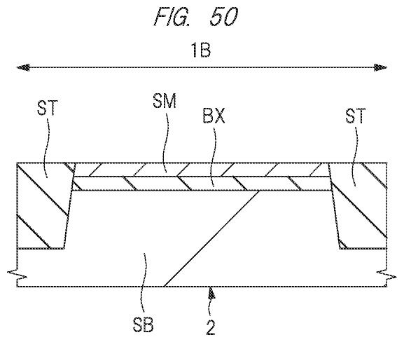

Next, as illustrated in FIGS. 48 to 50, the semiconductor layer SM and the insulating layer BX in the memory formation region 1A are removed by etching, and the semiconductor layer SM and the insulating layer BX in the peripheral circuit region 1B are not removed and left. As a result, in the memory formation region 1A, as illustrated in FIGS. 48 and 49, the semiconductor layer SM and the insulating layer BX do not exist, and the SOI substrate 2 is made of the semiconductor substrate SB. In the peripheral circuit region 1B, as illustrated in FIG. 50, the semiconductor layer SM and the insulating layer BX are left, and the SOI substrate 2 is made of the semiconductor substrate SB, the insulating layer BX on this, and the semiconductor layer SM on this, and this structure can be maintained until the manufacturing of the semiconductor device ends.

Regarding the subsequent steps, the present second embodiment is basically the same as the first embodiment in the memory formation region 1A. However, in the peripheral circuit region 1B, the present second embodiment is partially different from the first embodiment, and this different part will be mainly explained while explanation for the same part will be omitted or simplified below.

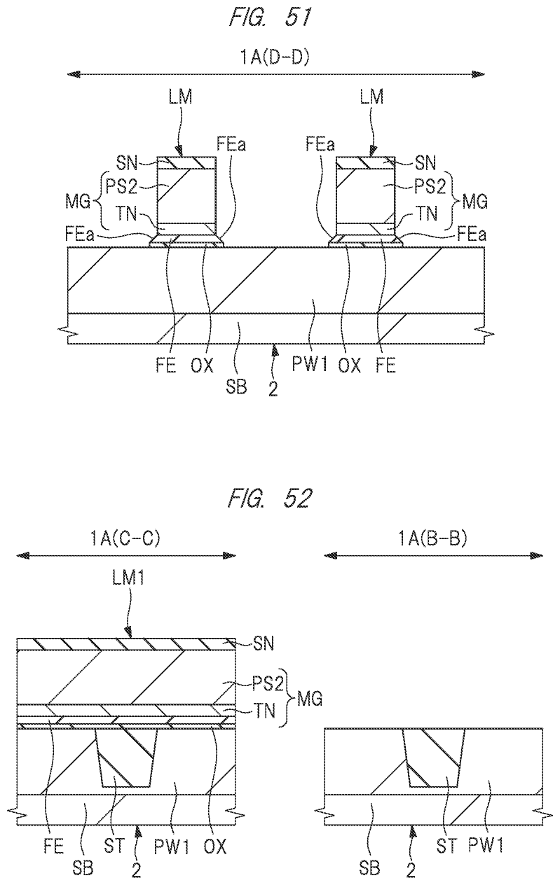

First, as similar to the first embodiment (as illustrated in FIGS. 6 and 7), the p-type well PW1 is formed in the semiconductor substrate SB in the memory formation region 1A also in the second embodiment. Then, the structure illustrated in FIGS. 51 to 53 corresponding to that in FIGS. 18 to 20 is provided by almost the same steps as explained with reference to FIGS. 9 to 20. The structure (the structure in the memory formation region 1A) illustrated in FIGS. 51 and 52 is basically the same as the structure (the structure in the memory formation region 1A) illustrated in FIGS. 18 and 19. On the other hand, in the peripheral circuit region 1B, while the insulating film GF is formed on the surface of the semiconductor substrate SB in the first embodiment, the insulating film GF in the present second embodiment is formed on the surface of the semiconductor layer SM as seen from FIG. 20. Therefore, in in the peripheral circuit region 1B in the present second embodiment, the structure body LM2 is formed on the semiconductor layer SM, and this point is different from the first embodiment.

Next, as similar to the first embodiment, the offset spacer OS is formed on each sidewall of the structure bodies LM1 and LM2, and then, the sidewall spacer SW1 is formed on each of the structure bodies LM1 and LM2 so as to arrange the offset spacer SW therebetween. As a result, the structure illustrated in FIGS. 21 and 22 is formed in the memory formation region 1A, and the structure illustrated in FIG. 54 is formed in the peripheral circuit region 1B. The case of FIG. 54 is different from the case of FIG. 23 in that the sidewall spacer SW1 is also formed on the structure body LM2 so as to arrange the offset spacer SW therebetween by etching back the insulating film ZM1.

Next, also in the present second embodiment, the dent portion KB is formed in the semiconductor substrate SB in the memory formation region 1A as illustrated in FIGS. 24 and 25 as similar to the first embodiment. In this case, the peripheral circuit region 1B is covered with a photoresist pattern or others to prevent the semiconductor layer SM from being etched.

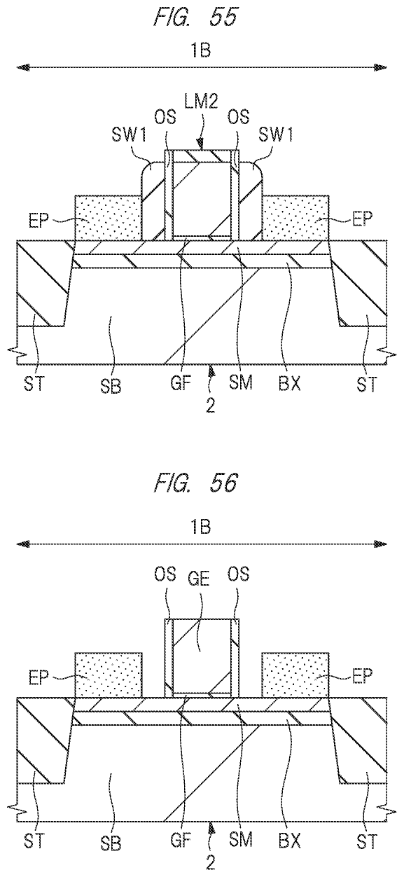

Next, also in the present second embodiment, the semiconductor layer EP is formed on the dent portion KB of the semiconductor substrate SB in the memory formation region 1A by the epitaxial growth method as illustrated in FIGS. 26 and 27 as similar to the first embodiment. In this case, as illustrated in FIG. 55, the semiconductor layer EP is also formed on the semiconductor layer SM in the peripheral circuit region 1B. In the peripheral circuit region 1B, the semiconductor layer EP is formed on a portion of the semiconductor layer SM, the portion being not covered with the structure body LM2, the offset spacer OS and the sidewall spacer SW1 but exposed.

Also in the present second embodiment, the sidewall spacer SW1 and the silicon nitride film SN are selectively removed by etching or others as similar to the first embodiment. As a result, the structure illustrated in FIGS. 28 and 29 is formed in the memory formation region 1A, and the structure illustrated in FIG. 56 is formed in the peripheral circuit region 1B.

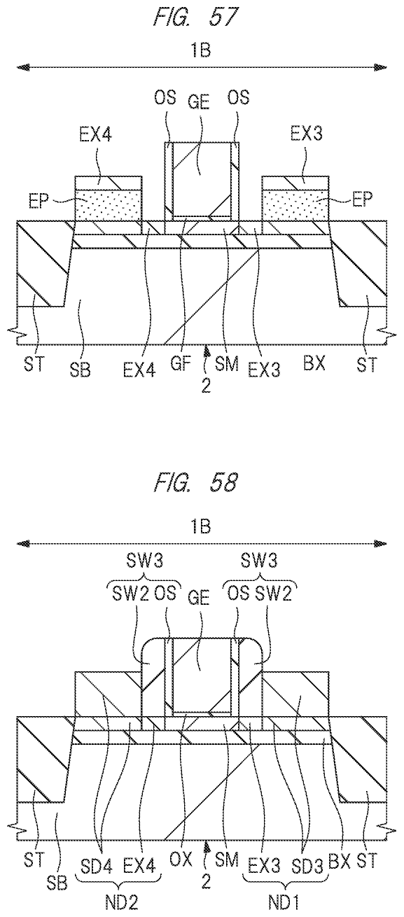

Next, n⁻-type semiconductor regions EX1 and EX2 are formed by ion implantation of an n-type impurity to the semiconductor substrate SB and the semiconductor layer EP in the memory formation region 1A as illustrated in FIGS. 31 and 32, and n⁻-type semiconductor regions EX3 and EX4 are formed by ion implantation of an n-type impurity to the semiconductor layers SM and EP in the peripheral circuit region 1B as illustrated in FIG. 57. Since the structure body LM2 can be functioned as a mask (ion-implantation blocking mask) in the peripheral circuit region 1B, the n-type impurity is not implanted to a region of the semiconductor layer SM in the peripheral circuit region 1B, the region being immediately below the structure body LM2.

Next, as illustrated in FIGS. 34, 35 and 58, the sidewall spacer SW2 is formed on each sidewall of the gate electrodes MG and GE so as to arrange the offset spacer OS therebetween as similar to the first embodiment. A combined body of the sidewall spacer SW2 and the offset spacer OS on the sidewall of the structure body LM1 becomes the sidewall spacer SW, and a combined body of the sidewall spacer SW2 and the offset spacer OS on the sidewall of the structure body LM2 becomes a sidewall spacer SW3.

Next, n⁻-type semiconductor regions SD1 and SD2 are formed by ion implantation of an n-type impurity to the semiconductor substrate SB and the semiconductor layer EP in the memory formation region 1A as illustrated in FIGS. 34 and 35, and n⁺-type semiconductor regions SD3 and SD4 are formed by ion implantation of an n-type impurity to the semiconductor substrate SB and the semiconductor layer EP in the peripheral circuit region 1B as illustrated in FIG. 58. Since the structure body LM2 and the sidewall spacer SW3 can be functioned as a mask (ion-implantation blocking mask) in the peripheral circuit region 1B, the n-type impurity is not implanted to a region of the semiconductor layer SM in the peripheral circuit region 1B, the region being immediately below the structure body LM2 and the sidewall spacer SW3. In the peripheral circuit region 1B, the n⁺-type semiconductor regions SD3 and SD4 are formed over the semiconductor layer EP and the semiconductor layer SM below this.

Next, activation annealing is performed. Then, as illustrated in FIGS. 37, 38 and 59, the metal silicide layer SL is formed by a silicide technique. The metal silicide layer SL in the peripheral circuit region 1B is formed on each of the surfaces of the n⁺-type semiconductor regions SD3 and SD4 (that is the surface of the semiconductor layer EP) and the upper surface of the gate electrode GE.

Next, as illustrated in FIGS. 40, 41 and 60, the insulating film IL1 is formed as an interlayer insulating film, and then, the contact hole CT is formed in this insulating film IL1, and the conductive plug PG is formed in the contact hole CT. Then, the insulating film IL2 and the wiring M1 are formed, and the structure as illustrated in FIGS. 40, 41 and 60 is provided. Then, the wirings and the insulating films in upper layers are formed.

The semiconductor device including the ferroelectric memory can be manufactured as described above.

In the present second embodiment, the semiconductor layer EP for the memory element MC configuring the ferroelectric memory and the semiconductor layer EP for the MISFET of the peripheral circuit are formed in the same step. Therefore, the semiconductor layer EP for the memory element MC (the semiconductor layer EP in the memory formation region 1A) can be formed together with the semiconductor layer EP (the semiconductor layer EP in the peripheral circuit region 1B) that is necessary for the formation of the MISFET of the peripheral circuit in the semiconductor layer SM of the SOI substrate without the separate addition of the epitaxial growth step for forming the semiconductor layer EP for the memory element MC. As a result, the number of steps of manufacturing the semiconductor device can be suppressed. Also, the manufacturing cost of the semiconductor device can be suppressed.

In the foregoing, the invention made by the present inventors has been concretely described on the basis of the embodiments. However, it is needless to say that the present invention is not limited to the foregoing embodiments, and various modifications can be made within the scope of the present invention.

What is claimed is:

1. A semiconductor device including a ferroelectric memory comprising:
a semiconductor substrate;
a gate electrode of the ferroelectric memory formed on the semiconductor substrate to arrange a ferroelectric film therebetween; and
an epitaxial semiconductor layer formed on the semiconductor substrate on both sides of the gate electrode,
wherein the epitaxial semiconductor layer is formed on a dent portion of the semiconductor substrate, and
at least a part of each of a source region and a drain region of the ferroelectric memory is formed in the epitaxial semiconductor layer.

2. The semiconductor device according to claim 1 further comprising:
an element isolation region embedded in a trench of the semiconductor substrate,
wherein a height position of a base surface of the dent portion is lower than a height position of an upper surface of the element isolation region.

3. The semiconductor device according to claim 2,
wherein the epitaxial semiconductor layer is adjacent to the element isolation region.

4. The semiconductor device according to claim 3,
wherein the height position of the base surface of the dent portion is lower by 20 nm or more than the height position of the upper surface of the element isolation region.

5. The semiconductor device according to claim 1,
wherein a side surface of the ferroelectric film tilts such that a width of the ferroelectric film in a first direction is larger as a portion of the side surface is closer from an upper surface of the ferroelectric film to a lower surface of the ferroelectric film, and
the first direction is a gate length direction of the gate electrode.

6. The semiconductor device according to claim 5,
wherein a thickness of the ferroelectric film is 5 to 15 nm.

7. The semiconductor device according to claim 5,
wherein difference between a width of the lower surface of the ferroelectric film in the first direction and a width of the upper surface of the ferroelectric film in the first direction is equal to or larger than 10 nm.

8. The semiconductor device according to claim 5,
wherein a height position of the upper surface of the epitaxial semiconductor layer is higher than a height position of the upper surface of the semiconductor substrate below the ferroelectric film.

9. The semiconductor device according to claim 5,
wherein a height position of the upper surface of the epitaxial semiconductor layer is higher than a height position of the upper surface of the ferroelectric film.

10. The semiconductor device according to claim 5,
wherein a silicon oxide film or a silicon oxynitride film is arranged between the ferroelectric film and the semiconductor substrate.

11. The semiconductor device according to claim 5 further comprising:
an interlayer insulating film formed on the semiconductor substrate so as to cover the gate electrode;
a contact hole formed in the interlayer insulating film; and
a conductive plug formed in the contact hole,
wherein the conductive plug is arranged on the epitaxial semiconductor layer to be electrically connected to the epitaxial semiconductor layer.

12. The semiconductor device according to claim 11,
wherein a metal compound layer is formed on an upper surface of the epitaxial semiconductor layer, and
the conductive plug is electrically connected to the epitaxial semiconductor layer through the metal compound layer.

13. The semiconductor device according to claim 1,
wherein the ferroelectric memory is a planar-type ferroelectric memory.

14. A semiconductor device including a ferroelectric memory comprising:
a semiconductor substrate;
an element isolation region embedded in a trench of the semiconductor substrate;
a gate electrode of the ferroelectric memory formed on the semiconductor substrate to arrange a ferroelectric film therebetween; and
an epitaxial semiconductor layer formed on the semiconductor substrate on both sides of the gate electrode,
wherein the epitaxial semiconductor layer is formed on a dent portion of the semiconductor substrate,
a height position of a base surface of the dent portion is lower than a height position of an upper surface of the element isolation region,
the epitaxial semiconductor layer is adjacent to the element isolation region,
a side surface of the ferroelectric film tilts such that a width of the ferroelectric film in a first direction is larger as a portion of the side surface is closer from an upper surface of the ferroelectric film to a lower surface of the ferroelectric film,
the first direction is a gate length direction of the gate electrode,
at least a part of each of a source region and a drain region of the ferroelectric memory is formed in the epitaxial semiconductor layer, and
a height position of an upper surface of the epitaxial semiconductor layer is higher than a height position of an upper surface of the ferroelectric film.

15. A method of manufacturing a semiconductor device including a ferroelectric memory comprising the steps of:
(a) preparing a semiconductor substrate;
(b) forming a gate electrode of the ferroelectric memory formed on the semiconductor substrate to arrange a ferroelectric film therebetween;
(c) after the step (b), forming a dent portion by etching the semiconductor substrate;
(d) forming an epitaxial semiconductor layer on the dent portion of the semiconductor substrate; and
(e) after the step (d), forming a source region and a drain region of the ferroelectric memory by an ion implantation method,
wherein at least a part of each of the source region and the drain region of the ferroelectric memory is formed in the epitaxial semiconductor layer.

16. The method of manufacturing the semiconductor device according to claim 15,
wherein the step (b) includes the steps of:
(b1) forming a first film for forming the ferroelectric film on the semiconductor substrate;
(b2) forming a second film for forming the gate electrode on the first film; and
(b3) forming the gate electrode on the semiconductor substrate so as to arrange the ferroelectric film therebetween by etching the second film and the first film,
wherein a side surface of the ferroelectric film formed in the step (b3) tilts such that a width of the ferroelectric film in a first direction is larger as a portion of the side surface is closer from an upper surface of the ferroelectric film to a lower surface of the ferroelectric film, and
the first direction is a gate length direction of the gate electrode.

17. The method of manufacturing the semiconductor device according to claim 15, further comprising the step of, after the step (a) and before the step (b):
(a1) forming an element isolation region in the semiconductor substrate by an STI method,
wherein a height position of a base surface of the dent portion formed in the step (c) is lower than a height position of an upper surface of the element isolation region, and
the epitaxial semiconductor layer formed in the step (d) is adjacent to the element isolation region,

18. The method of manufacturing the semiconductor device according to claim 15,
wherein a height position of a base surface of the dent portion formed in the step (c) is lower by 20 nm or more than a height position of an upper surface of the element isolation region.

19. The method of manufacturing the semiconductor device according to claim 15,
wherein a height position of an upper surface of the epitaxial semiconductor layer is higher than a height position of an upper surface of the ferroelectric film.

20. The method of manufacturing the semiconductor device according to claim 15, further comprising the step of:
(f) after the step (e), forming a metal compound layer on a surface of the epitaxial semiconductor layer;
(g) after the step (f), forming an interlayer insulating film on the semiconductor substrate so as to cover the gate electrode, the epitaxial semiconductor layer and the metal compound layer;
(h) forming a contact hole in the interlayer insulating film; and
(i) forming a conductive plug in the contact hole,
wherein the conductive plug is electrically connected to the metal compound layer.
